(19) United States
(12) Patent Application Publication
(10) Pub. No.: US 2025/0149559 A1
(43) Pub. Date: May 8, 2025

(54) Robust Anode Materials, Anode Layers and Methods of Making and Forming Same

(71) Applicant: Forge Nano, Inc., Thornton, CO (US)

(72) Inventors: Jaime DuMont, Thornton, CO (US); Barbara Hughes, Thornton, CO (US); Arrelaine Dameron, Boulder, CO (US); Madison Martinez, Thornton, CO (US); Brianna Boeyink, Thornton, CO (US); Meghan Herbert-Walters, Thornton, CO (US); David M. King, Sudbury, MA (US)

(21) Appl. No.: 18/940,809

(22) Filed: Nov. 7, 2024

Related U.S. Application Data
(60) Provisional application No. 63/596,894, filed on Nov. 7, 2023.

(51) Int. Cl. H01M 4/36; C23C 16/40; C23C 16/44; H01M 4/02; H01M 4/04; H01M 4/133; H01M 4/134; H01M 4/1393; H01M 4/1395; H01M 4/38; H01M 4/525; H01M 4/587; H01M 4/62; H01M 10/0525; H01M 10/42

(52) U.S. Cl. CPC H01M 4/366; C23C 16/403; C23C 16/405; C23C 16/4417; H01M 4/0447; H01M 4/133; H01M 4/134; H01M 4/1393; H01M 4/1395; H01M 4/364; H01M 4/386; H01M 4/525; H01M 4/587; H01M 4/62; H01M 10/0525; H01M 2004/027; H01M 2010/4292

(57) ABSTRACT

The inventors discovered a battery treatment and a battery with an atomic layer deposition (ALD) coating on a graphite powder in the anode that leads to superior properties enabling a short treatment time and excellent stability. A superior anode material is obtained by atomic layer deposition (ALD) onto graphite and/or silicon-graphite powder. Powder compositions and methods of forming them are described.

### RELATED APPLICATIONS

This application claims the priority benefit of U.S. Provisional Patent Application Ser. No. 63/596,894 filed Nov. 7, 2023.

### TECHNICAL FIELD

The present application relates to the field of lithium battery technologies, and in particular graphite and silicon carbon negative anode materials and preparation methods thereof, coatings for graphite and silicon carbon negative electrode materials and preparation methods thereof, and batteries including same.

### INTRODUCTION

Over the past 30 years since their inception, Li-ion batteries (LIBs) have become widely used in energy-intensive mobile electronic devices such as smartphones and other high-drain portable electronics, electric vehicles of all sizes and formats, etc., owing to their high energy density, long cycle life, and low self-discharge rates. Increasing the energy density of Li-ion batteries remains a crucial objective for the success of electric vehicles, grid-scale energy storage, and next-generation consumer electronics. Efforts are underway to continually improve the robustness and reliability and energy density of composite cathode and anode layers in high performance LIBs. Oxide-based cathode material developments typically focus on increasing nickel or manganese content while reducing cobalt content to reduce the cost/kWh of cathode materials, which are the most expensive component of LIBs. Graphite anode materials exhibit numerous advantages such as being inexpensive and highly stable (relative to high energy density cathode materials), but their limited capacity (theoretical capacity: 372 mAh/g) is becoming insufficient to achieve long-life LIB capacities that exceed 250, 275 or even 300+ Wh/kg. Si exhibits a high theoretical specific capacity of 3580 mAh/g upon conversion to the Li₁₅Si₄ alloy when cycled to its lowest discharge voltage.

Fully cycling a pure Si anode between Si and Li₁₅Si₄ is impractical, as structurally a large volume expansion occurs (˜400% by volume) while alloying a metal with Li. Silicon expands and contracts during the charging/discharging process through the formation of an electrochemical alloy with Li with State of Charge, commensurate with voltage thresholds. Graphite behaves similarly, but to a lesser extent; fully cycling a pure Graphite anode between C and Li₆C may only induce a ˜10 to 15% volumetric expansion. High volume changes in Si anode materials due to charging and discharging generate cracks on the surface of the active electrode material, and continuous cracks can cause micronization/pulverization of the Si particle surfaces. This micronization allows for new reactions with the electrolyte at newly exposed interfaces, creating a solid electrolyte interface (SEI) that depletes the electrolyte and causes rapid capacity fade and inadequate cycle life.

There are ongoing efforts to incrementally increase the capacity of the anode layers by replacing certain amounts of graphite in composite anode layers with Si (typically in the form of particles that may be cladded with electrochemically active carbon), to produce composite anode layers with capacities between 500 and 1000 mAh/g as a transitory and practical alternative to the more-challenging silicon-only or lithium metal anode layers. For example, replacing 15 to 25 wt % of graphite with silicon:graphite composite particles leads to a 10 to 15% or greater increase in usable energy density depending on final Si loading. However, there remain drawbacks to this approach as both the fundamental degradation mechanisms and volumetric expansion of graphite and silicon in composite anode layers are different, highly complex, and non-linear with respect to state of charge, charge/discharge rates, operating temperatures and overall usage profiles. For example, excessive localized expansion of silicon during lithiation will stochastically cause graphite particles to become electrically isolated from one another, leading to premature cell degradation. Electrolyte additives can be used to homogenize the degradation profiles, albeit at the expense of interfacial resistance; however, even if successful today, the value of this approach will soon be obsolete as energy density and cycle life demands are further increased.

One method for mitigating the drawback of using Si is to coat the Si-based anode with various materials, which suppress the volume expansion and prevent direct contact with the electrolyte. Various methods such as wet coating, physical vapor deposition, chemical vapor deposition (CVD), and atomic or molecular layer deposition (ALD or MLD) are employed to coat the anode with a suitable material. ALD is a promising coating method that can be used to deposit highly homogeneous and reproducible materials on a powder surface. Another advantage of the ALD process is that the weight loading (parts per million) of the coating layer can be finely adjusted by repeating cycles of the ALD process. MLD is an analog of ALD that can produce hybrid inorganic-organic or fully organic coating layers, which have been deployed to apply compressible coatings that can increase the structural integrity of silicon during volumetric changes due to lithiation and delithiation steps.

Coatings have become ubiquitous for cathode powders and anode powders, including graphite and silicon as a means to produce more robust LIBs that increase cycle life while reducing the cost/kWh of cells. However, it has been discovered that the coatings that are selected for each constituent electroactive material, despite being physically discrete and separate from one another, interact and require re-optimization when used in conjunction with one another. For example, nearly all commercial graphite powders are coated using an energy intensive pitch process derived from petroleum sources, which produces an irregular amorphous carbon shell that reduces defect sites and reduces exfoliation during lithiation/delithiation processes (pitch coating). Optimal ALD coatings for certain cathode materials paired with pitch-coated graphite (with or without its own ALD coating), are different when paired with synthetic or natural graphite intermediate particles that have not yet received a commercial pitch coating. Similarly, ALD coatings for robust anode layers comprising graphite and silicon cladded with carbon, graphite, graphene, etc. (hereafter simply generalized as “Si/G”) differ not only based on intrinsic properties of the Si/G material such as synthesis technique, crystallinity, surface area, pore volume, weight loadings, etc., but also extrinsic factors such as whether the graphite has a pitch coating and/or an ALD coating, and even the amount, role and function of the coating on the cathode material.

When lithium ions are alloyed with silicon, a series of polarizations are involved. Lithium ions in the electrolyte reach the surface of silicon wrapped with the solid electrolyte interface (SEI) layer, experiencing ohmic polarization represented by a solution resistance R_{S}. They enter the SEI layer from electrolyte and then move to silicon, overcoming activation polarizations relevant to each step (R_{SEI} and R_{CT}). After being alloyed with silicon, lithium ions are diffused throughout silicon mass along a concentration gradient (concentration polarization). When lithium ions are intercalated into graphite, many resistance categories are similar to those of anodes with which lithium can be alloyed. However, lithium can be intercalated and deintercalated much more readily from graphite, which results in much sharper peaks when observing the differential capacity (dQ/dV) from cycling curves. In dQ/dV plots of full cells, all anodic peaks for lithium intercalation into graphite and lithium alloying into silicon (or tin, etc.) tend to occur and be observable at voltages at or below ˜ 3.65V.

### SUMMARY OF THE INVENTION

In one aspect, the invention provides a battery, comprising: an anode, a cathode, a separator separating the anode and cathode, and a Li electrolyte; wherein the cathode comprises an active powder plus binder; wherein the active powder does not have an ALD coating; and wherein the anode comprises a coated graphite powder and a binder wherein the coated graphite powder comprises an ALD coating.

In any of the inventive aspects, the invention can be further described by one or any combination of the following: wherein the anode has a surface comprising Li₂O and Li₂CO₃ (this is typically formed after a cycling treatment); wherein the ALD coating is applied by 2 to 10 cycles of exposure to trimethylaluminum and water; wherein the ALD coating comprises a Ti or Al oxide coating; wherein the active powder is uncoated (this excludes active powders that are purchased with non-ALD coatings); wherein the battery is treated by a plurality of shallow formation cycles at a voltage between 3.7 and 4.4 V and a temperature of 20 to 35° C. followed by a full discharge; wherein the graphite powder has a surface comprising at least 20 and at most 140 ppm of Al or at least 20 and at most 140 ppm of Ti; wherein the anode further comprises a silicon-carbon composite powder (particles comprising silicon and carbon within each particle) and comprising a coating of an aluminum oxide or a titanium oxide or a zirconium oxide disposed over the silicon-carbon particles; wherein the Ti or Al is present only in the coating; wherein the coated graphite powder comprises at most 5% by weight of one or more conductive additives and at most 5% by weight of one or more binder materials.

In another aspect the invention provides a method of forming a battery, comprising: providing a battery comprising: an anode, a cathode, a separator separating the anode and cathode, and a Li electrolyte; wherein the cathode comprises an active powder plus binder; and wherein the anode comprises a coated graphite powder and a binder wherein the coated graphite powder comprises an ALD coating; and treating the battery with a plurality of shallow formation cycles at a voltage between 3.7 and 4.4 V and a temperature of 20 to 35° C. followed by a full discharge.

The invention can be further described by one or any combination of: wherein the treatment comprises 3 to 5 shallow formation cycles at a rate of C/4 to C/6 at between 3.8 and 4.3 V and a temperature of 25 to 33° C. followed by a full discharge to 3 V; wherein the treatment takes from 10 to 20 hours, or 13 to 17 hours; wherein the battery is the battery of claim 1.

In another aspect, the invention provides a mixture of a first powder and a second powder; wherein the first powder comprises a graphite powder comprising a coating of an aluminum oxide or a boron oxide or a titanium oxide or a zirconium oxide; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 20 and at most 140 ppm of Al or at least 20 and at most 140 ppm of B or at least 20 and at most 140 ppm of Ti or at least 20 and at most 140 ppm of Zr; wherein the second powder surface comprises at least 200 ppm and at most 500 ppm of Al, or at least 300 ppm and at most 900 ppm of Ti, or at least 300 ppm and at most 1200 ppm of Zr.

In a further aspect, the invention provides a composition, comprising: a mixture of a first anode active material powder and a second anode active material powder; wherein the first anode active material powder comprises a plurality of graphite particles comprising an outermost coating of an oxide of Al, B, Ti and/or Zr, and optionally Li; and optionally an amorphous carbon coating interposed between the graphite particles and the outermost coating; wherein the second anode active material powder comprises a plurality of silicon-carbon composite particles (particles comprising silicon and carbon within each particle) comprising an outermost coating of an oxide of Al, Ti and/or Zr, and optionally Li; wherein the graphite particles are selected from one the following (A-D):
A) graphite particles having the amorphous carbon coating and the outermost coating comprising at least 20 and at most 140 combined ppm of Al, B, Ti and/or Zr and less than 200 ppm Li;
B) graphite particles having the amorphous carbon coating and the outermost coating comprising at least 150 and at most 560 combined ppm of Al, B, Ti and/or Zr and at least 200 ppm Li;
C) graphite particles devoid of the amorphous carbon coating, and the outermost coating comprising between at least 400 and at most 2,800 combined ppm of Al, B, Ti and/or Zr and less than 200 ppm Li; and
D) graphite particles devoid of the amorphous carbon coating and the outermost coating comprising between at least 560 and at most 3,600 combined ppm of Al, B, Ti and/or Zr and at least 200 ppm Li; and
wherein the outermost coating of the plurality of silicon-carbon composite particles is selected from the following:
   i) at least 200 ppm and at most 500 ppm of Al and less than 200 ppm Li;
   ii) at least 300 ppm and at most 900 ppm of Ti and less than 200 ppm Li;
   iii) at least 300 ppm and at most 900 ppm of Zr and less than 200 ppm Li;
   iv) at least 300 combined ppm and at most 1,200 combined ppm of at least two of Al, Ti and Zr and less than 200 ppm Li;
   v) at least 200 ppm and at most 1,600 ppm of Al and at least 200 ppm Li;
   vi) at least 300 ppm and at most 3,600 ppm of Ti and at least 200 ppm Li;
   vii) at least 300 ppm and at most 3,600 ppm of Zr and at least 200 ppm Li;
   viii) at least 300 combined ppm and at most 3,600 combined ppm of at least two of Al, Ti and Zr and at least 200 ppm Li.

In another aspect, the invention provides a composition, comprising: a mixture of a first powder and a second powder; wherein the first powder comprises a graphite powder comprising a surface comprising lithium and aluminum, boron, titanium and/or zirconium; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 200 ppm of Li, and between 140 and 400 ppm of Al or between 140 and 400 ppm of B or between 140 and 560 ppm of Ti or between 140 and 560 ppm of Zr; wherein the second powder surface comprises at least 200 ppm of Li, and between 500 and 1600 ppm of Al, or between 900 and 3600 ppm of Ti or between 900 and 3600 ppm of Zr. The metal loading (including the sum of Li, Ti, and Al) on the second powder is preferably at least 50% or at least 200% greater on in the range up to 300% or 400% greater than the metal loading on the first powder.

In yet another aspect, the invention provides a composition, comprising: a mixture of a first powder a second powder and a third powder; wherein the first powder comprises a graphite powder comprising a surface comprising aluminum, boron, titanium and/or zirconium; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the third powder comprising carbon nanotubes present in an amount of 0.1 to 0.4 mass percent or less than 0.1 to 0.4 mass percent of the total mass of the mixture; wherein the first powder comprises a surface having between 215 and 245 ppm of Al, or 205 and 235 ppm of B, or between 440 and 490 ppm of Ti, or between 1035 and 1110 ppm of Zr; wherein the second powder comprises a surface having between 1200 and 1600 ppm of Al, Ti or Zr.

In another aspect, the invention provides a battery comprising: an anode, a cathode, a separator separating the anode and cathode, and a Li electrolyte; wherein the cathode comprises nickel-rich NMC (the atomic percentage of Ni is at least 51% of the Ni, Mn and Co) or manganese-rich NMC (the atomic percentage of Mn is at least 51% of the Ni, Mn and Co) powder and a binder; wherein the anode comprises the mixture of any of the compositions described herein and a binder; and wherein the battery when charged and discharged satisfies Relationships 1 & 2 as pertaining to a first peak and a second peak of a differential capacity (dQ/dV)−voltage charge/discharge plot:

$$2.95 < {V}_{s 1} < 3.05 < {V}_{t 1} < 3.15 and 3.25 < {V}_{l m 1} < 3 \text{.35} \qquad [ Relationship 1 ]$$

$$3.45 < {V}_{t 2} and 3.6 < {V}_{l m 2} < 3.70 \qquad [ Relationship 2 ]$$

In Relationship 1, which pertains to the first peak of the differential capacity (dQ/dV)−voltage charge/discharge plot proceeding in the direction of increasing potential: Vₛ₁ is a charge start voltage, as defined by the value of the differential capacity (dQ/dV)−voltage charge/discharge plot first deviates above dQ/dV=0.1 from the x-axis (dQ/dV=0); Vₜ₁ is the voltage value at a point where a tangent line to a value corresponding to 50% of the first peak value of the differential capacity (dQ/dV)−voltage charge/discharge plot intersects the line dQ/dV=0; V₁ₘ₁ is the voltage value at the local maximum of the first peak of the differential capacity (dQ/dV)−voltage charge/discharge plot. In Relationship 2, which pertains to the second peak of the differential capacity (dQ/dV)−voltage charge/discharge plot proceeding in the direction of increasing potential: Vₜ₂ is the voltage value at a point where a tangent line to a value corresponding to 50% of the second peak value of the differential capacity (dQ/dV)−voltage charge/discharge plot intersects the line dQ/dV=0; V₁ₘ₂ is the voltage value at the local maximum of the second peak of the differential capacity (dQ/dV)−voltage charge/discharge plot.

In another aspect, the invention provides a composition, comprising: a mixture of a first powder and a second powder; wherein the first powder comprises a graphite powder comprising a coating of an aluminum oxide or a titanium oxide; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 20 and at most 140 ppm of Al or at least 20 and at most 140 ppm of Ti; wherein the second powder surface comprises at least 200 ppm and at most 500 ppm of Al, at least 300 ppm and at most 900 ppm of Ti or at least 300 ppm and at most 900 ppm of Zr or at most 1200 ppm of Zr.

In another aspect, the inventive composition, comprises: a mixture of a first powder and a second powder; wherein the first powder comprises a graphite powder that does not comprise an amorphous carbon coating on the graphite powder; and comprising a surface comprising lithium and aluminum or titanium; wherein the second powder comprises a silicon-carbon composite powder (particles comprising silicon and carbon within each particle) and comprising a coating of an aluminum oxide or a titanium oxide or a zirconium oxide disposed over the silicon-carbon particles.

In a further aspect, the inventive composition, comprises: a graphite powder that does not comprise an amorphous carbon coating on the graphite powder; and comprising a coating of an aluminum oxide or a titanium oxide; wherein the graphite powder comprises a coating comprising Al oxide and/or Ti oxide; wherein the powder comprises at least 20 and at most 140 ppm of Al and/or at least 20 and at most 140 ppm of Ti.

The invention can, in any aspect, be further characterized by one or any combination of the following: wherein the metal loading on the second powder is at least 50% greater than the metal loading on the first powder; and in some preferred embodiments, at least 2× greater, in some embodiments in the range of at least 50% greater to 4× or 3×; wherein the first powder comprises a graphite powder comprising coating of an aluminum oxide; and wherein the first powder contains 20 to 140 ppm Al; preferably 70 to 100 ppm Al; wherein the second powder contains 340-430 ppm Al. Preferably, the metals are present primarily (greater than 50%) or exclusively in the coatings (the coating as opposed to a core can be identified by electron microscopy); wherein (the metal loading on the second powder)/surface area of the second powder) is at least 20% greater than (the metal loading on the first powder)/surface area of the first powder); further comprising at least 200 ppm Li in the first powder and the second powder.

In another aspect, the invention provides an anode comprising any of the compositions described here. The anode does not include the current collector. Typically, the anode is made by compressing the mixture of the first and second powders along with a binder. In some embodiments, the anode comprises at most 5% by weight of one or more conductive additives and at most 5% by weight of one or more binder materials. In some preferred embodiments, the anode comprises at least 15% by weight of the second powder, and which, when tested according to Testing Procedure 1, exhibits a discharge capacity of at least 100 mAh/g, preferably at least 200 mAh/g, and that decreases by 10% or less between 150 and 250 cycles. Preferably, the anode comprises at most 0.5% or 1.0% by weight of one or more conductive additives and at least 15% by weight of the second powder and at most 4.5% by weight of one or more binder materials. The anode does not include the current collector.

In another aspect, the invention provides a method of making an anode (or a method of increasing the discharge capacity of an anode), comprising: providing a powder comprising carbon-containing particles; and coating the powder by ALD with a Li[M]Ox coating wherein the powder comprises at least 800 ppm M and at least 200 ppm Li; and forming an anode from a powder composition comprising the coated powder. In some embodiments, the molar ratio of Li:M is in the range of 0.25 to 0.35. The anode does not include the current collector. Typically, the anode is made by compressing the mixture of the first and second powders along with a binder. Typically, the anode is made by compressing the mixture of the first and second powders along with a binder. The anode can be made with no carbon black and/or no carbon nanotubes, and/or no conductive additive.

In a further aspect, the invention provides a composition, comprising: a mixture of a first powder and a second powder; wherein the first powder comprises a graphite powder comprising a surface comprising lithium and aluminum or titanium; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 200 ppm of Li, and between 140 and 400 ppm of Al or between 140 and 560 ppm of Ti; wherein the second powder surface comprises at least 200 ppm of Li, and between 500 and 1600 ppm of Al, or between 900 and 3600 ppm of Ti or between 900 and 3600 ppm of Zr. In some preferred embodiments, the metal loading on the second powder is at least 50% greater than the metal loading on the first powder; and in some preferred embodiments, at least 2× greater, in some embodiments in the range of at least 50% greater to 4× or less or 3× or less.

In one aspect, the invention provides a composition, comprising: a mixture of a first powder and a second powder; wherein the first powder comprises a graphite powder comprising a coating of an aluminum oxide or a boron oxide or a titanium oxide or a zirconium oxide; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 20 and at most 140 ppm of Al or at least 20 and at most 140 ppm of B or at least 20 and at most 140 ppm of Ti or at least 20 and at most 140 ppm of Zr; wherein the second powder surface comprises at least 200 ppm and at most 500 ppm of Al, at least 300 ppm and at most 900 ppm of Ti or at least 300 ppm and at most 1200 ppm of Zr.

The invention can, in any aspect, be further characterized by one or any combination of the following: wherein the metal loading of the metal oxide disposed over the second powder is at least 50% greater than the metal loading of the metal oxide on the first powder; and in some preferred embodiments, at least 2× greater, in some embodiments in the range of at least 50% greater to 4× or less or 3× or less; wherein the first powder comprises a graphite powder comprising coating of an aluminum oxide; and wherein the first powder contains 20 to 140 ppm Al; preferably 70 to 100 ppm Al; wherein the second powder contains 340-430 ppm Al. Preferably, the non-silicon metals are present primarily or exclusively in the coatings; wherein (the metal loading of the metal oxide disposed over the second powder)/surface area of the second powder) is at least 20% greater than (the metal loading of the metal oxide on the first powder)/surface area of the first powder); further comprising at least 200 ppm Li in the first powder and the second powder. Active materials are well known and may include one or any combination of the following: lithium nickel cobalt aluminum oxide (NCA), lithium cobalt oxide (LiCoO2), lithium iron phosphate (LiFePO4), lithium nickel cobalt aluminum oxide (NCA), and lithium manganese oxide (LiMn2O4).

In a further aspect, the invention provides a composition, comprising: a mixture of a first powder and a second powder; wherein the first powder comprises a graphite powder comprising a surface comprising lithium and aluminum, boron, titanium and/or zirconium; wherein the second powder comprises a silicon-carbon composite powder (particles comprising silicon and carbon within each particle) and comprising a coating of an aluminum oxide or a titanium oxide or a zirconium oxide disposed over the silicon-carbon particles; wherein the first powder surface comprises at least 200 ppm of Li, and between 140 and 400 ppm of Al or between 140 and 400 ppm of B or between 140 and 560 ppm of Ti or between 140 and 560 ppm of Zr; wherein the second powder surface comprises at least 200 ppm of Li, and between 500 and 1600 ppm of Al, or between 900 and 3600 ppm of Ti or between 900 and 3600 ppm of Zr. In some preferred embodiments, the metal loading on the second powder is at least 50% greater than the metal loading on the first powder; and in some preferred embodiments, at least 2× greater, in some embodiments in the range of at least 50% greater to 4× or less or 3× or less.

The invention can, in any aspect, be further characterized by one or any combination of the following: wherein the metal loading on the second powder is at least 50% greater than the metal loading on the first powder having the amorphous carbon coating; and in some preferred embodiments, at least 2× greater, in some embodiments in the range of at least 50% greater to 4× or less or 3× or less; wherein the first powder comprises a graphite powder comprising the amorphous carbon coating interposed between the graphite particles and the outermost coating comprising 20 to 140 ppm Al, B, Ti or Zr; preferably 70 to 100 ppm Al, Zr or Ti; wherein the first powder comprises a graphite powder devoid of an amorphous carbon coating interposed between the graphite particles and the outermost coating comprising 600 to 1,250 ppm Al, Zr or Ti; preferably 600 to 850 ppm Al, 800 to 1,250 Zr or 500 to 1,250 ppm Ti; or the outermost coating comprising 600 to 1,250 total ppm of two or more of Al, Zr and Ti; wherein the second powder contains 340-430 ppm Al. Preferably, the metals are present primarily or exclusively in the coatings; wherein (the metal loading on the second powder)/surface area of the second powder) is at least 20% greater than (the metal loading on the first powder)/surface area of the first powder); further comprising at least 200 ppm Li in the first powder and the second powder.

The invention provides a composite anode for a lithium secondary battery that comprises at least a first anode active material powder and a second anode active material powder, wherein the first anode active material powder comprises a plurality of particles into which lithium can intercalate and does not comprise particles that can with which lithium can alloy, and the second anode active material powder comprises a plurality of particles with which lithium can alloy and optionally into which lithium can intercalate, and wherein each plurality of particles comprises a coating that shifts the voltage at which a peak differential capacity occurs during lithiation and/or delithiation of each plurality of particles. The invention provides a composite anode for a lithium secondary battery that comprises at least two active materials, wherein one active material comprises graphitic carbon with no silicon and the other active material comprises silicon and optionally carbon, and wherein each active material comprises a coating that shifts the onset voltage at which the differential capacity first exceeds 5% of the peak differential capacity during lithiation and/or delithiation, for both graphite and silicon.

Another aspect of the present application provides a graphite negative electrode material having a first metal oxide coating and a silicon carbon negative electrode material having a second metal oxide coating, wherein a battery composed of a negative electrode prepared by the mixture of the graphite negative electrode material and the silicon carbon negative electrode material as a working electrode, wherein the negative electrode further comprises less than 1.0 wt % carbon nanotubes and less than 3.0 wt % binder materials, a cathode electrode comprising nickel-rich or manganese-rich NMC cathode active materials, and an electrolyte containing a lithium ion conductive substance is charged and discharged, and in a case of drawing a relationship graph between a differential value dQ/dV obtained by differentiating a charging and discharging capacity Q by a working electrode potential V and the working electrode potential V, when energizing the negative electrode material in a direction of delithiation, observing a first potential V1 at which first local maximum of dQ/dV occurs between 3.25 V and 3.35 V, observing a second potential V2 at which the next local maximum of dQ/dV occurs (along the path of increasing potential) between 3.6 V and 3.7 V, and wherein V1 and V2 shifted by at least +10 mV from that of an analogous battery constructed using the same silicon carbon negative electrode material devoid of the first metal oxide coating. A further aspect of the present application provides the herein referenced graphite negative electrode material having the first coating wherein a battery composed of a negative electrode prepared without the silicon carbon negative electrode material as a working electrode, wherein the negative electrode further comprises less than 1.0 wt % carbon nanotubes and less than 3.0 wt % binder materials, a cathode electrode comprising nickel-rich or manganese-rich NMC cathode active materials, and an electrolyte containing a lithium ion conductive substance is charged and discharged, and in a case of drawing a relationship graph between a differential value dQ/dV obtained by differentiating a charging and discharging capacity Q by a working electrode potential V and the working electrode potential V, when energizing the negative electrode material in a direction of delithiation, observing a third potential V3 at which a local maximum of dQ/dV occurs between 3.40 V and 3.50 V, wherein the third potential V3 is shifted by at least −15 mV from that of an analogous battery constructed using the same graphite negative electrode material devoid of the first metal oxide coating.

Any of the inventive aspects can be combined with the any of the other aspects. The invention also includes methods of making anodes or making batteries using any of the materials and procedures described herein.

The invention can, in any aspect, be further characterized by one or any combination of the following: wherein the surface of the first powder comprises lithium titanium nitride, lithium titanium oxide, or a mixture thereof; wherein the surface of the first powder comprises lithium aluminum oxide, lithium aluminum nitride, or a mixture thereof; and wherein the coating comprises lithium aluminum oxide, lithium titanium oxide, lithium zirconium oxide, or a mixture thereof.

The invention can possess unexpected and superior results. For example, the discharge capacity trended down as metal loading (Zr) on the silicon-carbon particles increased from 498 to 825 ppm even while Li increased from about 175 to about 275 ppm. However, increasing metal loading to a higher level (1070 ppm Zr) surprisingly increased discharge capacity.

Unless specified to the contrary, “ppm” refers to the composition of a powder as measured by ICP-OES (Inductively Coupled Plasma-Optical Emission Spectroscopy) of the powder. So, for example, the phrase “a powder surface comprises 200 ppm Li,” means that when the powder is measured by ICP-OES it indicates 200 ppm Li. This value is for the entire powder; however, knowledge of the synthesis or characterization of the coated particle can be conducted to specify the distribution of Li (or any element of interest) in the particles. Typically, the metals are concentrated in the coating, so the concentration of metals in the coating itself are significantly higher; however, the ppm are for the entire particle due to the measurement technique.

A graphite powder has the conventional meaning in the art; typically a powder that comprises at least 90 mass % C, preferably at least 95 mass % C; small amounts of oxygen and other elements are sometimes present.

A silicon-carbon powder also has its conventional meaning. The silicon and carbon are primarily elemental silicon and elemental carbon rather than oxides or other forms of these materials. Throughout this disclosure, “primarily” has the conventional meaning of greater than 50%. The mass ratio of Si/C in these particles is typically in the range of 2 to 0.7, or 1.5 to 1.0.

As is conventional, silicon is a semi-metal and is not considered a metal.

The term “oxide” is discussed elsewhere in this description. Preferably, an oxide comprises the metal typically in the stable oxidation state (Al3+, Ti4+, Zr4+, although lower oxidation states can be present) and at least 90 mass % or at least 95 mass % of the counterions are oxygen. Likewise, in a nitride at least 90 mass % or at least 95 mass % of the counterions are nitrogen, and in an oxynitride, at least 90 mass % or at least 95 mass % of the counterions are oxygen and nitrogen. The coatings can alternatively comprise nitrides or oxynitrides.

The invention is typically defined using the term “comprising” meaning “including;” however, any of the inventive aspects can alternatively be described using the narrower terms “consisting essentially of” or “consisting of” to exclude components that would materially affect the invention or exclude other components, respectively. The invention may be further characterized by any of the data presented here. For example, any of the inventive aspects can be described as possessing one or any combination of the properties or compositions (or within ±10%, ±20%, or ±30% of one or any combination of the properties or compositions) described herein. All ranges are inclusive and combinable. For example, when a range of “1 to 5’ is recited, the recited range should be construed as including ranges “1 to 4”, “1 to 3”, “1-2”, “1-2 & 4-5”, “1-3 & 5”, “2-5”, any of 1, 2, 3, 4, or 5 individually, and the like.

The invention includes: particle mixtures, electrodes (typically anodes), batteries comprising the anodes, methods of making any of the inventive compositions, and methods of storing and discharging electrical power.

### BRIEF DESCRIPTION OF THE DRAWINGS

FIG. 1 shows the differential capacity (dQ/dV)-voltage charge/discharge plot improved kinetics of 50 ppm coating by Atomic Layer Deposition on spheroidized graphite particles having an amorphous carbon coating (pitch coating) at a charging rate of 4C.

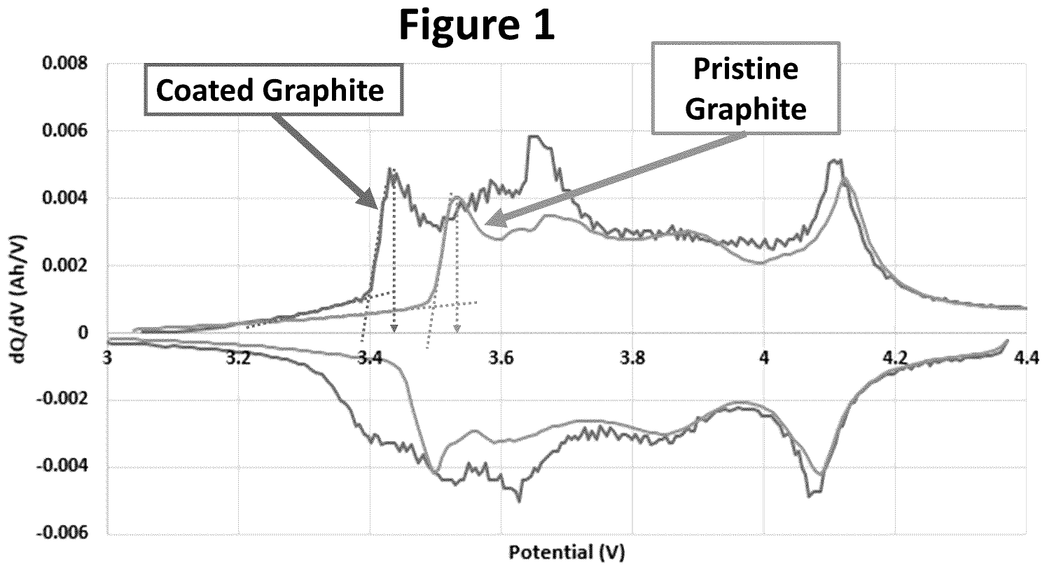

FIG. 2 shows the differential capacity plots (dQ/dV) of commercial graphite with and without Al₂O₃ ALD coatings, showing lithium intercalation voltage peak shifts of +15 mV at 46 ppm Al, +10 mV at 66 ppm Al, −30 mV at 443 ppm Al and −50 mV at 634 ppm Al.

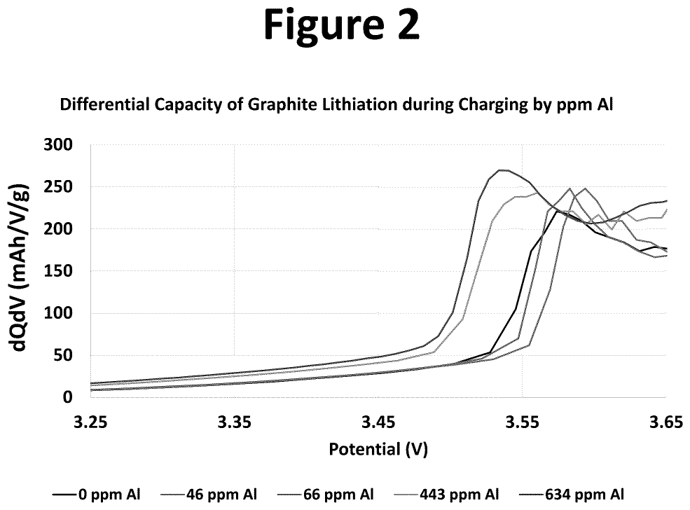

FIG. 3 shows the differential capacity plots (dQ/dV) of commercial graphite with and without TiO₂ ALD coatings, showing lithium intercalation voltage peak shifts of −90 mV at 446 ppm Ti.

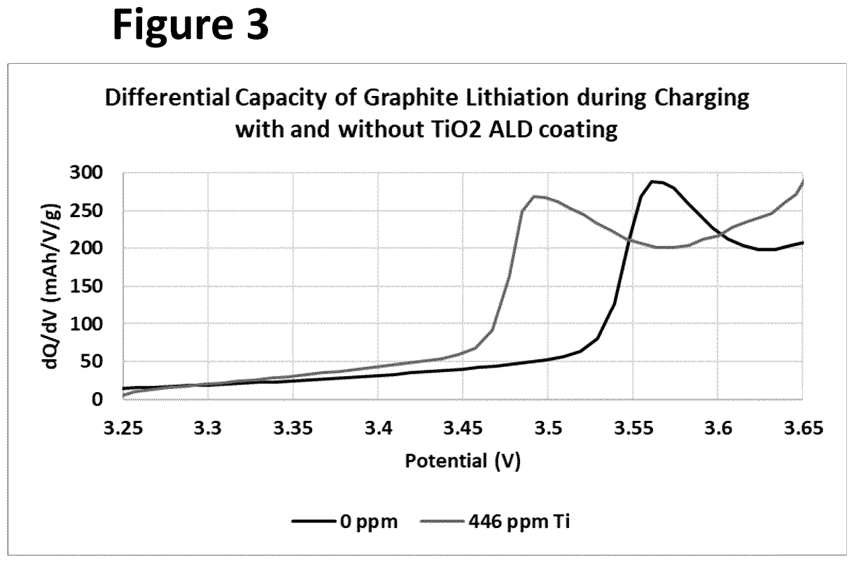

FIG. 4 shows the differential capacity plots (dQ/dV) of commercial graphite with ZrO₂ or LiₓZrO_{y} ALD coatings, showing lithium intercalation voltage peak shifts of −50 mV at 1,069 ppm Zr in ZrO₂, and −90 mV at 2,559 ppm Zr and 90 ppm Li in LiₓZrO_{y}.

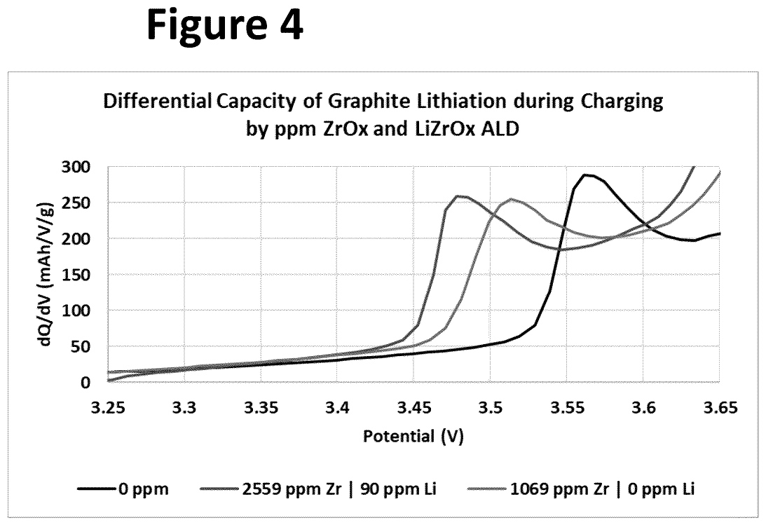

FIG. 5 shows the differential capacity plots (dQ/dV) of Si/C-G composite anodes, showing lithium alloying voltage peaks shifting by +70 mV at the Li_{3.5}Si to Li_{2.0}Si transition and +50 mV at the Li_{2.0}Si to Si transition for both 202 ppm Al and 385 ppm Al.

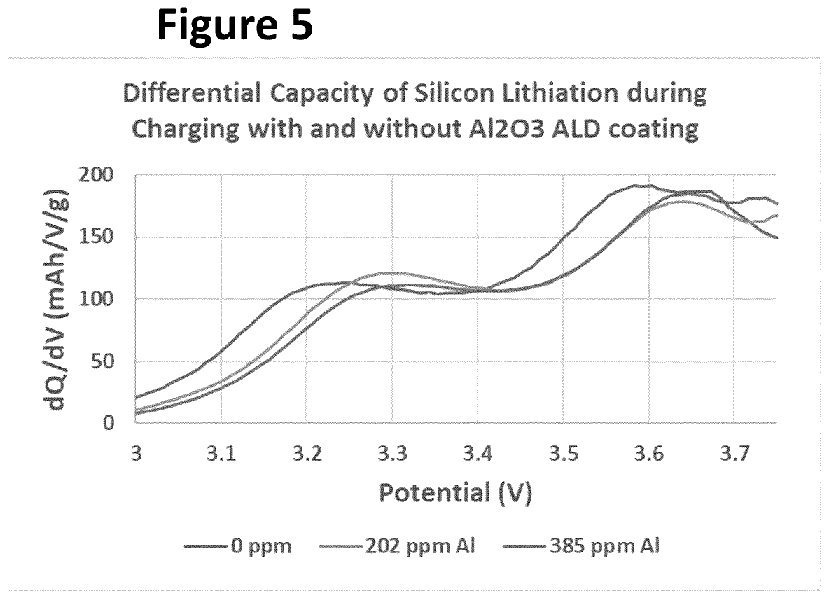

FIG. 6 shows the differential capacity plots (dQ/dV) of Si/C-G composite anodes, showing lithium alloying voltage peaks shifting over 102 Discharge Cycles after formation for Pristine and 202 ppm Al samples.

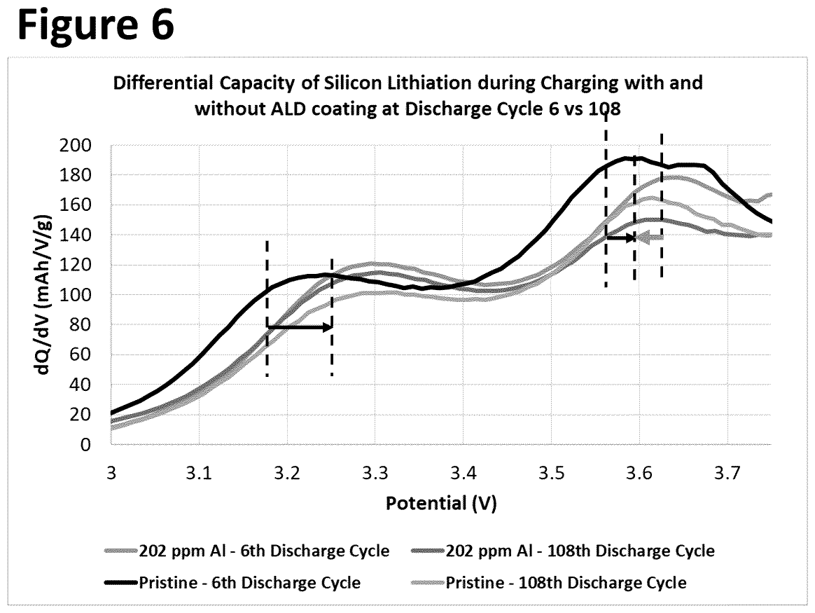

FIG. 7 depicts how the unexpected ability to shift the Lithium-Silicon alloying voltage in a positive direction with certain ALD coatings, and shift the Lithium-Graphite intercalation voltage in a negative direction, can reduce competition between the Si—Li_{2.0}Si alloy transition and the C—Li₆C intercalation transition.

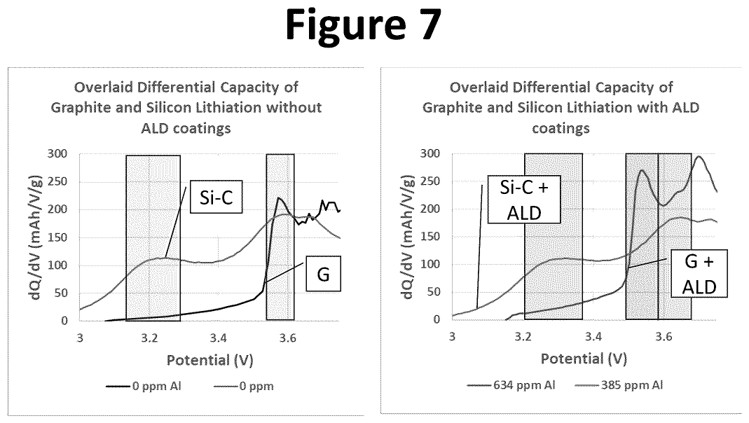

FIG. 8 depicts the first and second dQ/dV peaks of the inventive cell with ALD coated Silicon-carbon anode materials, and how to mathematically deconvolute the two peaks such that the voltages of Relationship 1 and Relationship 2 can be calculated.

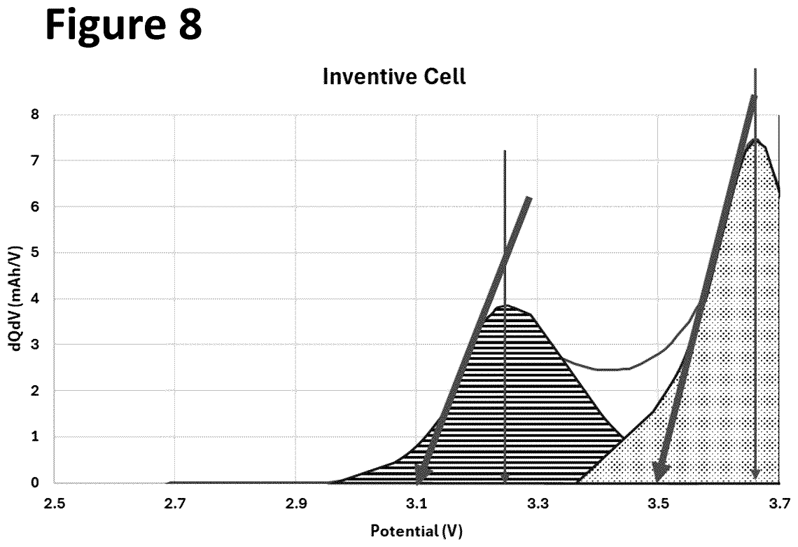

FIG. 9 depicts how the methodology shown in FIG. 8 can be applied to a comparative cell with silicon-carbon anode materials, but without ALD coatings, and how this comparative cell does not satisfy Relationships 1 and 2.

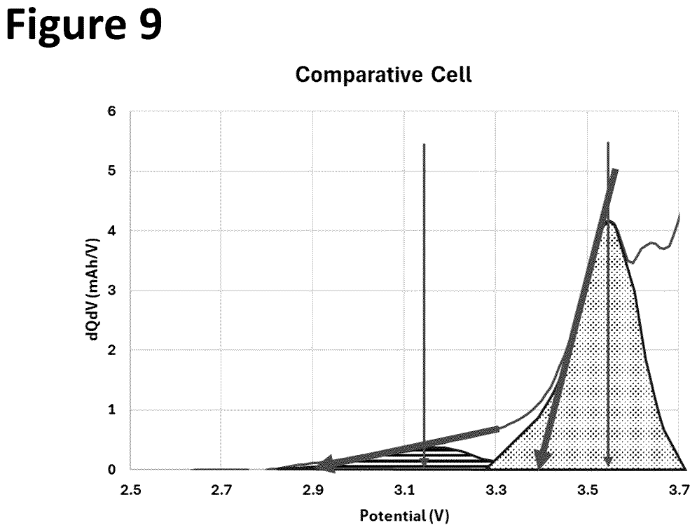

FIG. 10 depicts elemental mapping of Al, C and O for Al2O3 ALD coated graphite powder, and Si, C and Al for Al2O3 ALD coated silicon-carbon powder, showing the unexpected difference in deposition uniformity between anode active material substrates both comprising carbon surfaces.

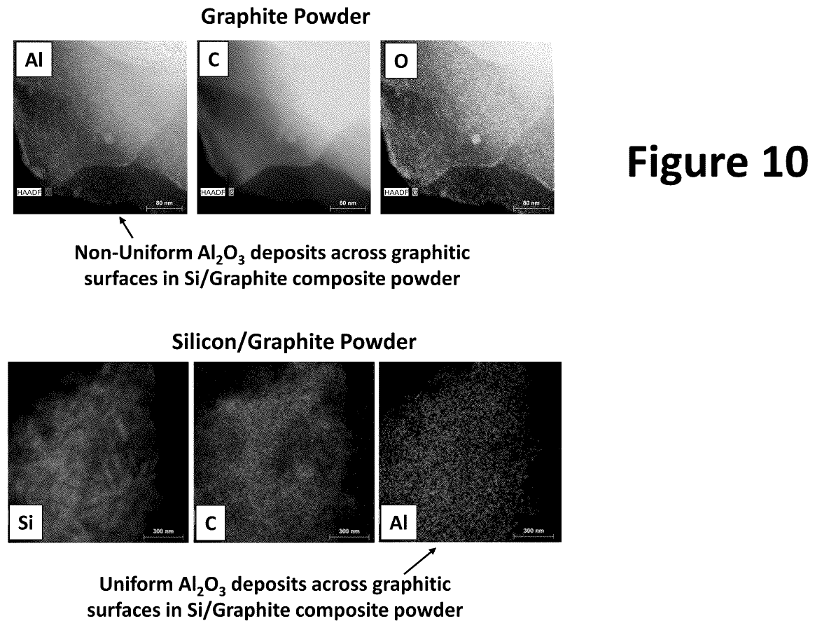

### DETAILED DESCRIPTION OF THE INVENTION

An anode material is one that can reversibly intercalate lithium ions during a battery charging cycle and release lithium ions into a battery electrolyte solution (with production of electrons) during a battery discharge cycle. Suitable anode materials include, for example, carbonaceous materials such as graphite, carbonized pitch, carbon fibers, porous glassy carbon, graphitized mesophase microspheres, furnace black, acetylene black and various other graphitized materials. Other materials such as lithium, silicon, germanium and molybdenum oxide are useful anode materials. Particles can be engineered to contain two or more of these anode materials, such as silicon-carbon particles that comprise a mixture of elemental silicon and carbon. In addition, mixtures of two or more types of anode material particles can be used.

For silicon-carbon particles preferably, the silicon is primarily or fully amorphous silicon. Preferably, the carbon is a material known as hard carbon; however, other forms of carbon such as carbon black, char, charcoal, graphite, natural graphite, amorphous graphite, synthetic graphite, pyrolytic graphites such as plant-derived carbons and bio-derived carbons, and soot may also be used. In some preferred embodiments, the silicon-carbon particles in the second powder have a particle diameter (size) such that at least 70 mass % or at least 90 mass % of the silicon-carbon particles have a size in the range of 500 nm to 20 μm, or a size in the range of 1 μm to 15 μm, or a size in the range of 2 μm to 14 μm. In some preferred embodiments, the silicon-carbon particles in the second powder have a surface area such that at least 70 mass % or at least 90 mass % of the silicon-carbon particles have a BET surface area in the range of 1.0 to 8.0 m²/g; or 2.0 to 7.5 m²/g, or 3.0 to 6.5 m²/g, or 3.5 to 5.5 m²/g. The mass ratio of Si to C in the particles is preferably in the range of 0.1 to 0.7 or 0.2 to 0.65 or 0.3 to 0.6 or 0.45 to 0.60. The mass ratio of the first and second powders is preferably in the range of 0.85 to 0.30 or 0.7 to 0.4 or 0.65 to 0.50.

Furthermore, an anode material that comprises graphite particles, prior to coating, can be any type of graphite, and can be selected from (but not limited to): natural graphite, amorphous graphite, synthetic graphite, pyrolytic graphite. Anode materials, for example graphite particles, preferably have a particle diameter or longest measurable dimension (size) such that at least 70 mass % or at least 90 mass % of the carbon particles have a size in the range of 500 nm to 20 μm, or a size in the range of 1 μm to 15 μm, or a size in the range of 2 μm to 12 μm. As is conventional for this size range, particle size refers to the size of individual particles, not the size of a cluster (in the case of agglomerated particles). Graphite particles preferably have a surface area such that at least 70 mass % or at least 90 mass % of the carbon particles have a BET surface area in the range of 1.0 to 8.0 m²/g; or 1.5 to 6 m²/g, or 1.5 to 3.0 m²/g.

Suitable methods for constructing lithium ion battery electrodes include those described, for example, in U.S. Pat. No. 7,169,511. The electrodes are each generally in electrical contact with or formed onto a current collector. A binder, if used, is generally an organic polymer, such as a poly (vinylidene fluoride), polytetrafluoroethylene, a styrene-butadiene copolymer, an isoprene rubber, a poly(vinyl acetate), a poly(ethyl methacrylate), polyethylene, carboxymethylcellulose or nitrocellulose. 2-ethylhexylacrylate-acrylonitrile copolymers, and the like. The binder is generally nonconductive or at most slightly conductive.

An electrode can be assembled from the binder and one or more anode material powders in any convenient manner. The binder is typically used as a solution or in the form of a dispersion (as in the case of a latex) or in the form of an ink or paste. In many cases, the binder can simply be mixed with the electrode particles, formed into the appropriate shape and then subjected to conditions (generally including an elevated temperature) sufficient to remove the solvent or latex continuous phase.

The binder/particle mixture may be cast onto or around a support (which may also function as a current collector) or into a form. A suitable current collector for the anode is made of a metal or metal alloy such as copper, a copper alloy, nickel, a nickel alloy, titanium, stainless steel and the like. The binder/particle mixture may be impregnated into various types of mechanical reinforcing structures, such as meshes, fibers, and the like, in order to provide greater mechanical strength to the electrode. Upon removing the solvent or carrier fluid, the electrode particles become bound together by the binder to form a solid electrode. The electrode is often significantly porous, and processes known in the art such as pressing or calendering are used to reduce electrode porosity.

Alternatively, dry (solvent-free) and binder-free processes are increasingly known in the art and are also suitable for the production of the anode layers of this invention.

Inactive particulate materials may also be incorporated into the electrode. These include conductive materials such as carbon particles, carbon nanotubes and the like. Inactive particulate materials are ones that are not relied upon to reversibly intercalate lithium ions during a battery charging cycle and release lithium ions into a battery electrolyte solution (with production of electrons) during a battery discharge cycle, and typically comprise less than 10% by weight of the electrode, or less than 6% by weight of the electrode, or less than 4% by weight of the electrode, or less than 2.5% by weight of the electrode, or less than 1% by weight of the electrode, or between 0.65% and 0.95% by weight of the electrode.

The coating can be continuous or discontinuous. The coating is not metallic. The Al, Ti, Zr, and/or Li are preferably deposited onto the particles by ALD. These metals are typically present in the form of oxides (hydroxyls may also be present), but may alternatively be in the form of nitrides or oxynitrides. In some embodiments, the metals in the coating are present in an amount of 0.2 mass % or more, or 0.5 mass % or more, or 0.8 mass % or more, or in the range of 0.2 to 3 or 0.3 to 2.0 mass % of the particles (or, alternatively, as mass % of the sum of the core and coating (ignoring other layers such as layers subsequently applied that overlay the coating)). In some embodiments, the maximum average thickness of the coating is at least 0.5 nm or at least 1 nm and/or a at most 20 nm or at more 100 nm or at most 1 μm.

### General Description of Atomic or Molecular Layer Deposition

Atomic layer-controlled growth techniques permit the deposition of coatings of about 0.1 to about 5 angstroms in average thickness per reaction cycle, and thus provide a means of extremely fine control over surface coverage or coating thickness. Thicker coatings can be prepared by repeating the reaction sequence to sequentially deposit additional layers of the coating material until the desired coating thickness is achieved.

The coating is deposited in an Atomic Layer Deposition (ALD) or Molecular Layer Deposition (MLD) process. In the ALD/MLD process, the coating-forming reaction is conducted as a series of (typically) two half-reactions. In each of these half-reactions, a single reagent (precursor) is introduced into contact with the substrate surface. Conditions are such that the reagent is in the form of a gas. In most cases, the reagent reacts with functional groups on the surface of the particle and becomes bound to the particle. Because the reagent is a gas, it permeates into pores in the substrate and deposits onto the interior surfaces of the pores as well as onto the exterior surfaces of the substrate. This precursor is designed to react with the surface at all of the available surface sites but not react with itself. In this way, the first reaction occurs to form a single monolayer, or sub-monolayer, and creates a new surface functionality. Excess amounts of the reagent are then removed, which helps to prevent the growth of undesired, larger inclusions of the coating material. Each remaining half-reaction is then conducted in turn, each time introducing a first reagent, allowing it to react at the surface of the particle, and removing excess reagent before introducing the next reagent. Usually, an inert carrier gas is used to introduce the reagents, and the reaction chamber is usually swept with the carrier gas between successive reagent introductions to help remove excess reagents and gaseous reaction products. A vacuum may be pulled during and between successive dosings of reagents, to further remove excess reagents and gaseous reaction products.

After exposure to the first precursor, the surface is then exposed to the second precursor, also typically dispersed in an inert carrier gas. This precursor is designed to react with the functional groups put down in the first reaction step. This reaction also happens until all of the available surface sites are reacted. The second precursor also does not react with itself. Any excess of the second precursor is also removed in an optional inert gas purge step. If the gases are metered properly, the purge step may be unnecessary. This may be at least a 4 step process (precursor 1, purge, precursor 2, purge) to deposit one monolayer of the film which is being grown. This is not meant to imply only a single precursor because some ALD and MLD processes use multiple reactants in a step, for example APTES/H₂O/O₃ for depositing SiO₂. This process is repeated as many times as is necessary to build up the desired film thickness. The ALD/MLD process may start with a “linker” agent, or pre-treatment gas (such as ozone), that facilitates covalent bonding to the surface, or it may end with a terminating agent that may be hydrophobic, hydrophilic, or otherwise engineered for a specific purpose.

For purposes of the present invention, the ALD/MLD process may include only a half reaction, rather than a full cycle. However, at least one full cycle is preferred, more preferably at least five cycles.

A convenient method for applying the coating to a particulate substrate is to form a fluidized or otherwise agitated bed of the particles, and then pass the various reagents in turn through the fluidized bed under reaction conditions. Methods of fluidizing particulate materials are well known, and generally include supporting the particles on a porous plate or screen. A fluidizing gas is passed upwardly through the plate or screen, lifting the particles somewhat and expanding the volume of the bed. With appropriate expansion, the particles behave much as a fluid. Reagents (in gaseous, liquid, or solid phase) can be introduced into the bed for reaction with the surface of the particles. Liquid or solid reagents convert to gaseous form once inside the bed prior to reaction with particles. In this invention, the fluidizing gas also can act as an inert purge gas for removing unreacted reagents and volatile or gaseous reaction products. In addition, the reactions can be conducted at particle surfaces in a rotating cylindrical vessel, a rotating tube, or a vibrating bed. This vibrating bed method is particularly suitable for continuous processes.

Reaction conditions are selected mainly to meet three criteria. The first criterion is that the reagents are gaseous under the conditions of the reaction. Therefore, temperature and pressure conditions are selected such that the reactants volatilize before reaction. The second criterion is one of reactivity. Conditions, particularly temperature, are selected such that the desired reaction between the film-forming reagents (or, at the start of the reaction, the first-introduced reagent and the particle surface) occurs at a commercially reasonable rate. The third criterion is that the substrate is thermally stable, from a chemical standpoint and from a physical standpoint. The substrate should not degrade or react at the process temperature, other than a possible reaction on surface functional groups with one of the ALD precursors at the early stages of the process. Similarly, the substrate should not melt or soften at the process temperature, so that the physical geometry, especially pore structure, of the substrate is maintained. The reactions are generally performed at temperatures from about 270 to 1000 K, preferably from 290 to 450 K, with specific temperatures in each case being below the temperature at which the substrate melts, softens or degrades.

Between successive dosings of the reagents, the particles are subjected to conditions sufficient to remove reaction products and unreacted reagents. This can be done, for example, by subjecting the particles to a high vacuum, such as about 10⁻⁵ Torr or greater, after each reaction step. Another method of accomplishing this, which is more readily applicable for industrial application, is to sweep the particles with an inert purge gas between the reaction steps. This purge gas can also act as a fluidizing medium for the particles and as a carrier for the reagents.

Several techniques are useful for monitoring the progress of the reaction. For example, vibrational spectroscopic studies can be performed using transmission Fourier transform infrared techniques. The deposited coatings can be examined using in situ spectroscopic ellipsometry. Atomic force microscopy studies can be used to characterize the roughness of the coating relative to that of the surface of the substrate. X-ray photoelectron spectroscopy and x-ray diffraction can be used to do depth-profiling and ascertain the crystallographic structure of the coating.

Aluminum oxide coatings are conveniently deposited using trimethylaluminum and water as the precursors, as illustrated by reaction sequence A1/B1. The illustrated reactions are not balanced, and are only intended to show the reactions at the surface of the substrate (i.e., not inter- or intralayer reactions).

Substrate-XH*+Al(CH₃)₃=Substrate-X—Al*−CH₃+CH₄ (precursor reaction)

Substrate-X—Al*-CH₃+H₂O=Substrate-X—Al—OH*+CH₄ (A1)

Substrate-X—Al—OH*+Al(CH₃)₃=Substrate-X—Al—O—A-1*-CH₃+CH₄ (B1)

In reactions A1/B1, X is typically oxygen, nitrogen or sulfur, and the asterisk (*) represents the surface species at which the next half-reaction can occur. An aluminum oxide film is built up by repeating reactions A1 and B1 in alternating fashion, until the desired coating thickness is achieved. Aluminum oxide films tend to grow at a rate of approximately 0.1 nm/cycle using this reaction sequence.

Titanium oxide coatings are conveniently deposited using titanium tetrachloride and water and/or hydrogen peroxide as the precursors, as illustrated by reaction sequence A2/B2. As before, the illustrated reactions are not balanced, and are only intended to show the reactions at the surface of the particles (i.e., not inter- or intralayer reactions).

Substrate-XH*+TiCl₄=Substrate-X—Ti*-Cl₃+HCl (precursor reaction)

Substrate-X—Ti*-Cl₃+H₂O₂=Substrate-X-T-i*-OH+HCl+Cl₂ (A2)

Substrate-X—Ti*-OH+TiCl₄

Substrate-X—Ti—O—Ti*-Cl₃+-HCl (B2)

In reactions A2/B2, X is typically oxygen, nitrogen or sulfur, and the asterisk (*) represents the surface species at which the next half-reaction can occur. A titanium oxide film is built up by repeating reactions A2 and B2 in alternating fashion, until the desired coating thickness is achieved. Titanium oxide films tend to grow at a rate of approximately 0.05-0.1 nm/cycle using this reaction sequence.

As is known for ALD/MLD processes, the order can be AB, ABC, ABCD, ABCDABABCD, or any desired order provided that the chemical entities react with each other in the desired order. Each of the reactants has at least two reactive moieties (this includes the possibility that the reactant is modifiable to have two reactive moieties such as having a first reactive moiety and a second reactive moiety that is temporarily blocked by a protecting group or requires activation for subsequent reaction such as UV activation). In some preferred embodiments, the reactants have exactly two reactive moieties since higher numbers of reactive groups may lead to lower packing density. In some preferred embodiments, the films have at least three repeating units (e.g., ABABAB), or at least 5, or at least 10, or at least 50, and sometimes in the range of 2 to 1000, or 5 to 100. By “reactive” it is meant under normal MLD conditions and commercially relevant timescales (for example, at least 50% reacted within 10 hours under appropriate reaction conditions). For control of film quality, the reactants may be singly reactive during each step of the MLD process to avoid reacting twice to the surface, and the reactants should not self-react and condense onto the surface.

In some preferred embodiments, the reactive moieties for Reactant A may comprise: isocyanates (R-NCO), acrylates, carboxylic acids, esters, epoxides, amides and amines, and combinations thereof. In some preferred embodiments, Reactant A comprises a diisocyanate, a diacrylate, a dicarboxylic acid, a diester, diamide or a diamine. In some preferred embodiments, the reactive moieties on Reactant B comprise: alcohols or amines, and combinations thereof. In some preferred embodiments, Reactant B comprises a diol, an amine alcohol, or a diamine.

An inorganic layer applied to the particle in a first step preferably becomes covalently bonded to the substrate. Covalent bonding can occur when the first-to-be-applied precursor compound reacts under the conditions of the atomic layer deposition process with a functional group on the surface of the substrate. Examples of such functional groups are, for example, hydroxyl, carbonyl, carboxylic acid, carboxylic acid anhydride, carboxylic acid halide, primary or secondary amino.

Some ALD coatings are aluminum oxide and/or titanium oxide coatings. “Aluminum oxide” is used herein to designate a coating that is made up substantially entirely of aluminum and oxygen atoms, without reference to the specific stoichiometry. In many cases, it is expected that an aluminum oxide coating will correspond somewhat closely to the empirical structure of alumina, i.e., Al₂O₃, although deviations from this structure are common and may be substantial. “Titanium oxide” is used herein to designate a coating that is made up substantially entirely of titanium and oxygen atoms, without reference to the specific stoichiometry. In most cases, it is expected that a titanium oxide coating will correspond closely to the empirical structure of titania, i.e., TiO₂, although deviations from this structure are common and may be substantial. Similarly, considerations apply to understanding the other formulations described herein; although in some embodiments, the invention can be more specifically defined by the use of terms such as “consisting of.”

Except for the case of a half-reaction included in the broader aspects of the present invention, the atomic layer deposition process is characterized in that at least two different reactants are needed to form the coating layer. The reactants are introduced into the reaction zone individually, sequentially and in the gas phase. Excess amounts of reactant are removed from the reaction zone before introducing the next reactant. Reaction by-products are removed as well, between successive introductions of the reagents. This procedure ensures that reactions occur at the surface of the substrate, rather than in the gas phase.

A purge gas is typically introduced between the alternating feeds of the reactants, in order to further help to remove excess reactants. A carrier gas, which is usually but not necessarily the same as the purge gas, generally (but not always necessarily) is introduced during the time each reactant is introduced. The carrier gas may perform several functions, including (1) facilitating the removal of excess reactant and reaction by-products and (2) distributing the reactant through the reaction zone, thereby helping to expose all surfaces to the reactant. The purge gas does not react undesirably with the ALD reactants or the deposited coating, or interfere with their reaction with each other at the surface of the substrate.

Temperature and pressure conditions will depend on the particular reaction system, as it remains necessary to provide gaseous reactants. As is known for ALD/MLD processes, the temperature should be high enough to enable reactants in the gas phase but not so high that the product degrades.

The coating may comprise any coating that can be applied by molecular or atomic layer deposition. Some well-known coatings that can be applied to the metallic or other material core particle may comprise: oxides or mixed oxides (e.g., Al₂O₃, TiO₂, ZnO, ZrO₂, SiO₂, HfO₂, Ta₂O₅, LiNbₓO_{y}), nitrides (e.g., TiN, TaN, W₂N, TiY₂N), sulfides (e.g., ZnS, CdS, SnS, WS₂, MoS₂, ZnIn₂S₄), and phosphides (e.g., GaP, InP, Fe_{0.5}Co_{0.5}P). Some lesser known materials that can be applied to the core particle may comprise: transition metals (e.g., of Al, Cu, Co, W, Cr, Fe, Zn, Zr, Pt, Pd), metal fluorides (e.g., AlF₃, MgF₂, ZnF₂), oxy fluorides and oxy nitrides of transition metals, lanthanides in either elemental, oxide, fluoride, nitride, boride, or sulfide form (e.g., Y, YN, La₂O₃, LaF₃, Nb, Dy₂O₃, Nd, LaB₆, La₂S₃ etc), borides (e.g., TiB₂), carbides (e.g., B₄C, WC), silanes, silicides and other silicon containing materials, carbon-containing materials including, but not limited to, polymers (e.g., polyamides, polyethylenes, polyamides, polyureas, polyurethanes), hydrocarbons, polymers or fragments of amino acids or other biological-related molecules and polymers, and other materials), fluorinated polymers (e.g., fluoro or perfluoro-polyamides,-polyethylenes,-polyamides,-polyureas,-urethanes,-hydrocarbons). This coating is highly uniform over the particle; preferably, there is no more than a 20%, more preferably no more than 10%, or no more than 5% variation in coating thickness over the surface of the particle. This high level of uniformity is a characteristic of the ALD/MLD process. Particles coated by ALD/MLD are distinguishable from particles coated by other methods by 1) the uniformity of film thickness and 2) the lack of change in particle size distribution of the individual core particles, which are not possible with other techniques.

Coatings, on core powders, typically have a thickness in the range of 0.1 to 100 nm; preferably 0.2 to 50 nm; more preferably 0.5 to 10 nm, or 0.2 nm to 2 nm. Coating thickness can be measured by transmission electron microscopy (TEM). An ALD/MLD coating may cover 20% of the surface or less, or at least 20% of the surface, or at least 60% of the surface, or at least 80%, or at least 95% and still more or at least 99% of the surface area of the particles.

### EXAMPLES

Lithium nickel manganese cobalt oxide (LiNi_{0.8}Mn_{0.1}Co_{0.1}O₂, NMC811, Gelon Lib Co., Ltd.) and SLC1520T graphite (Superior Graphite) were selected as the cathode and anode materials. Forge Nano performed ALD coatings on batches of powder (6-10 kg each) using one of their fluidized bed reactor particle ALD coating tools using trimethylaluminum and water, resulting in approximately 0.3 nm of alumina on the NMC811 and approximately 0.2 nm on the graphite.

Each slurry was mixed using a planetary mixer (Ross PDM-1/2) and coated onto either aluminum or copper foil (MTI Corporation) using a pilot-scale slot-die coater (Frontier Industrial Technology). The total mass loading of the cathode and anode was approximately 11.1 mg/cm² and 7.1 mg/cm², respectively, with a porosity of around 35%.

### Protocol P2-30

The formation cycling of single-layer pouch cells, voltage monitoring of three-electrode pouch cells, and electrochemical impedance measurements (ranging from 500 kHz to 10 mHz) were performed using a VMP-3 potentiostat (Biologic, France) in a temperature chamber (ESPEC) set to a constant temperature of either 30° C. or 45° C. Following formation, all cells underwent long-term cycling tests on a Maccor battery cycler (Series 4000) at a constant temperature of 30° C.

The formation cycling protocol for P2-30 was to first charge the cells at a C/3 rate to 3.9 V, which was followed by 4 shallow formation cycles at a C/5 rate between 3.9 and 4.2 V, and then finally full discharge the cell at a C/3 rate to 3.0 V, all of which was carried out at a constant temperature of 30° C. Protocol P2-30 represents a fast formation protocol, lasting approximately 14-16 hours, and the majority of the time is spent between 3.9 V and 4.2 V to target the high state of charge (SOC) region where most SEI and CEI are formed. This represents approximately a 60% reduction in formation time compared to Protocol P1-30

### Protocol P1-30 (Baseline Comparative Protocol)

The formation cycling protocol for P1-30 was to charge and discharge the cells at a C/5 rate between 3.0 and 4.2 V at a constant temperature of 30° C. through four full formation cycles. This takes about 40 hours.

### Comparative Example 1

An array of Al₂O₃ ALD coating processes (1 to 10 cycles) was applied to a commercial graphite powder (d50≈7 microns). Before processing, the uncoated powder was sampled for ICP-OES, BET and moisture analysis. ICP-OES measured a baseline 0 ppm Al content. Moisture analysis measured a baseline range of 14-40 ppm H₂O. BET measured a 2.87 m²/g surface area for the uncoated powder. To prep the materials for coating, 3 kg of graphite powder was loaded into an 8 L stainless steel reactor body and mounted to a pilot scale (1-10 kg) fluidized bed reactor. The powder was fluidized in a stream of N₂ carrier gas which flowed through a 5 μm porous gas distribution disc located at the bottom of the 8 L reactor. Four 10 μm porous candlestick filters prevented elutriation of particles from the top. These parameters resulted in a 13.1 Torr dose line pressure before the powder bed and a bed pressure of 1.6 Torr. The gas flowing through the powder bed was monitored in situ by a quadrupole mass spectrometer located downstream from the reactor. The reactor body was heated to 180° C. and dried overnight until the ratio of the partial pressures of H₂O⁺ (m/z=18) and N₂⁺ (m/z=28) were less than 0.5%. Once the powder was dry, 1 cycle of an Al₂O₃ ALD coating was applied to the graphite powder using alternating pulses of trimethylaluminum (TMA) and deionized H₂O. Both chemical precursors were held at 35° C. and pulsed through metering valves to control their partial pressures. Depositions were monitored with the quadrupole mass spectrometer to ensure the expected reaction byproducts were observed during the ALD process. The presence of dimethyl aluminum⁺ (m/z=57) indicated the completion of the TMA half reaction while the presence of H₂O⁺ (m/z=18) indicated the completion of the H₂O half reaction. In the first ALD cycle, the TMA dose and H₂O dose were allowed to reach saturation of the powder bed. When the ALD process was complete, the reactor was cooled to room temperature and the full 3 kg of graphite powder was recovered. 20 g of the powder bed was sampled for ICP-OES and moisture analysis. ICP-OES analysis measured 9-14 ppm Al. Moisture analysis remained consistent with that of the uncoated material.

### Comparative Example 2

The procedure of Comparative Example 1 was followed to apply 2 Al₂O₃ ALD cycles onto a 3 kg batch of the commercial graphite powder (d50≈7 microns) of Comparative Example 1. The ICP-OES analysis for aluminum measured 23-28 ppm Al. Moisture analysis remained consistent with that of the uncoated material.

### Comparative Example 3

The procedure of Comparative Example 1 was followed to apply 3 Al₂O₃ ALD cycles onto a 3 kg batch of the commercial graphite powder (d50≈7 microns) of Comparative Example 1. The ICP-OES analysis for aluminum measured 32-38 ppm Al. Moisture analysis remained consistent with that of the uncoated material.

### Comparative Example 4

The procedure of Comparative Example 1 was followed to apply 5 Al₂O₃ ALD cycles onto a 3 kg batch of the commercial graphite powder (d50≈7 microns) of Comparative Example 1. The ICP-OES analysis for aluminum measured 66-75 ppm Al. Moisture analysis remained consistent with that of the uncoated material.

### Comparative Example 5

The procedure of Comparative Example 1 was followed to apply 7 Al₂O₃ ALD cycles onto a 3 kg batch of the commercial graphite powder (d50≈7 microns) of Comparative Example 1. The ICP-OES analysis for aluminum measured 125-132 ppm Al. Moisture analysis remained consistent with that of the uncoated material.

### Comparative Example 6

The procedure of Comparative Example 1 was followed to apply 10 Al₂O₃ ALD cycles onto a 3 kg batch of the commercial graphite powder (d50≈7 microns) of Comparative Example 1. The ICP-OES analysis for aluminum measured 185-195 ppm Al. Moisture analysis remained consistent with that of the uncoated material.

### Comparative Example 7

The procedure of Comparative Example 1 was followed to apply 1 TiO₂ ALD cycles onto a 3 kg batch of the commercial graphite powder (d50≈7 microns) of Comparative Example 1. The ICP-OES analysis for titanium measured 32 ppm Ti. Moisture analysis remained consistent with that of the uncoated material.

### Comparative Example 8

The procedure of Comparative Example 1 was followed to apply 2 TiO₂ ALD cycles onto a 3 kg batch of the commercial graphite powder (d50≈7 microns) of Comparative Example 1. The ICP-OES analysis for titanium measured 64 ppm Ti. Moisture analysis remained consistent with that of the uncoated material.

### Comparative Example 9

The procedure of Comparative Example 1 was followed to apply 3 TiO₂ ALD cycles onto a 3 kg batch of the commercial graphite powder (d50≈7 microns) of Comparative Example 1. The ICP-OES analysis for titanium measured 89 ppm Ti. Moisture analysis remained consistent with that of the uncoated material.

### Example 1

The procedure of Comparative Example 6 was followed to apply 10 Li[Al]Ox ALD cycles onto a 3 kg batch of the commercial graphite powder (d50≈7 microns) of Comparative Example 1, except an additional sequence was interleaved between each Al₂O₃ ALD cycle, comprising exposing the powder to a lithium-containing precursor, followed by a first purge step, followed by the same H2O exposure step of Example 1, followed by a second purge step. The ICP-OES analysis for aluminum measured 181-193 ppm Al and 205-215 ppm Li. Moisture analysis remained consistent with that of the uncoated material.

### Example 2

An array of Al₂O₃ ALD coating processes (1 to 10 cycles) was applied to a pre-commercial silicon-graphite (Si/G) composite powder (45-48% Silicon, balance graphite; d10≈2 microns d50≈8 microns, d90≈14 microns). Before processing, the uncoated powder was sampled for ICP-OES, BET and moisture analysis. ICP-OES measured a baseline 0 ppm Al content. Moisture analysis measured a baseline range of 280-315 ppm H2O. BET measured a 4.35-4.48 m²/g surface area for the uncoated powder. To prep the materials for coating, 3 kg of Si/G powder was loaded into an 8 L stainless steel reactor body and mounted to a pilot scale (1-10 kg) fluidized bed reactor. The powder was fluidized in a stream of N₂ carrier gas which flowed through a 5 μm porous gas distribution disc located at the bottom of the 8 L reactor, in the same manner described in Comparative Example 1. Four 10 μm porous candlestick filters prevented elutriation of particles from the top. These parameters resulted in a 13.3 Torr dose line pressure before the powder bed and a bed pressure of 1.8 Torr. The gas flowing through the powder bed was monitored in situ by a quadrupole mass spectrometer located downstream from the reactor. The reactor body was heated to 180° C. and dried overnight until the ratio of the partial pressures of H₂O⁺ (m/z=18) and N₂⁺ (m/z=28) were less than 0.5%. Once the powder was dry, 1 cycle of an Al₂O₃ ALD coating was applied to the Si/G powder using alternating pulses of trimethylaluminum (TMA) and deionized H₂O. Both chemical precursors were held at 35° C. and pulsed through metering valves to control their partial pressures. Depositions were monitored with the quadrupole mass spectrometer to ensure the expected reaction byproducts were observed during the ALD process. The presence of dimethyl aluminum⁺ (m/z=57) indicated the completion of the TMA half reaction while the presence of H₂O⁺ (m/z=18) indicated the completion of the H₂O half reaction. In the first ALD cycle, the TMA dose and H₂O dose were allowed to reach saturation of the powder bed.

When the ALD process was complete, the reactor was cooled to room temperature and the full 3 kg of Si/G powder was recovered. 20 g of the powder bed was sampled for ICP-OES and moisture analysis. ICP-OES analysis measured 202 ppm Al. Moisture analysis remained consistent with that of the uncoated material.

### Example 3

The procedure of Example 2 was followed to apply 2 Al₂O₃ ALD cycles onto a 3 kg batch of the pre-commercial Si/G powder (d50≈8 microns) of Example 2. The ICP-OES analysis for aluminum measured 385 ppm Al. Moisture analysis remained consistent with that of the uncoated material.

### Example 4

The procedure of Example 2 was followed to apply 3 Al₂O₃ ALD cycles onto a 3 kg batch of the pre-commercial Si/G powder (d50≈8 microns) of Example 2. The ICP-OES analysis for aluminum measured 385 ppm Al. Moisture analysis remained consistent with that of the uncoated material.

### Example 5

The procedure of Example 2 was followed to apply 1 Al₂O₃ ALD cycles onto a 3 kg batch of a higher surface area pre-commercial Si/G powder (Surface Area≈7.7-7.9 m²/g), otherwise using the same procedure of Example 2. The ICP-OES analysis for aluminum measured 325-339 ppm Al. Moisture analysis remained consistent with that of the uncoated material.

### Example 6

The procedure of Example 2 was followed to apply 3 Al₂O₃ ALD cycles onto a 3 kg batch of the higher surface area pre-commercial Si/G powder of Example 5. The ICP-OES analysis for aluminum measured 880-895 ppm Al. Moisture analysis remained consistent with that of the uncoated material.

### Example 7

The procedure of Example 2 was followed to apply 8 Al₂O₃ ALD cycles onto a 3 kg batch of the pre-commercial Si/G powder of Example 5. The ICP-OES analysis for aluminum measured 385 ppm Al. Moisture analysis remained consistent with that of the uncoated material.

### Example 8

The procedure of Example 2 was followed to apply 1 TiO₂ ALD cycles onto a 3 kg batch of the pre-commercial Si/G powder (d50≈8 microns) of Example 2. The ICP-OES analysis for aluminum measured 179 ppm Ti. Moisture analysis remained consistent with that of the uncoated material.

### Example 9

The procedure of Example 2 was followed to apply 1 TiO₂ ALD cycles onto a 3 kg batch of the pre-commercial Si/G powder (d50≈8 microns) of Example 2. The ICP-OES analysis for aluminum measured 399 ppm Ti. Moisture analysis remained consistent with that of the uncoated material.

### Example 10

The procedure of Example 2 was followed to apply 3 TiO₂ ALD cycles onto a 3 kg batch of the pre-commercial Si/G powder (d50≈8 microns) of Example 2. The ICP-OES analysis for aluminum measured 780 ppm Ti. Moisture analysis remained consistent with that of the uncoated material.

### Example 11

The procedure of Example 2 was followed to apply 5 TiO₂ ALD cycles onto a 3 kg batch of the pre-commercial Si/G powder (d50≈8 microns) of Example 2. The ICP-OES analysis for aluminum measured 1,350 ppm Ti. Moisture analysis remained consistent with that of the uncoated material.

### Example 12

The procedure of Example 2 was followed to apply 8 TiO₂ ALD cycles onto a 3 kg batch of the pre-commercial Si/G powder (d50≈8 microns) of Example 2. The ICP-OES analysis for aluminum measured 3,867 ppm Ti. Moisture analysis remained consistent with that of the uncoated material.

### Example 13

The procedure of Example 2 was followed to apply 1 ZrO₂ ALD cycles onto a 3 kg batch of the pre-commercial Si/G powder (d50≈8 microns) of Example 2. The ICP-OES analysis for zirconium measured 310 ppm Zr. Moisture analysis remained consistent with that of the uncoated material.

### Example 14

The procedure of Example 2 was followed to apply 2 ZrO₂ ALD cycles onto a 3 kg batch of the pre-commercial Si/G powder (d50≈8 microns) of Example 2. The ICP-OES analysis for zirconium measured 616 ppm Ti. Moisture analysis remained consistent with that of the uncoated material.

### Example 15

The procedure of Example 2 was followed to apply 3 ZrO₂ ALD cycles onto a 3 kg batch of the pre-commercial Si/G powder (d50≈8 microns) of Example 2. The ICP-OES analysis for zirconium measured 890 ppm Zr. Moisture analysis remained consistent with that of the uncoated material.

### Example 16

The procedure of Example 2 was followed to apply 4 ZrO₂ ALD cycles onto a 3 kg batch of the pre-commercial Si/G powder (d50≈8 microns) of Example 2. The ICP-OES analysis for zirconium measured 1,330 ppm Zr. Moisture analysis remained consistent with that of the uncoated material.

### Example 17

The procedure of Example 1 was followed to apply an array of LiZrOx ALD cycles, supercycles and dosing approaches each onto 3 kg batches of the pre-commercial Si/G powder (d50≈8 microns) of Example 2. The ICP-OES analysis for lithium and zirconum measured in accordance with the following table. Moisture analysis remained consistent with that of the uncoated material.

| | | Zr |
|---|---|---|
| | Li PPM | PPM |
| Example 17a | 160 | 498 |
| Example 17b | 280 | 825 |
| Example 17c | 305 | 1070 |
| Example 17d | 273 | 317 |
| Example 17e | 305 | 501 |
| Example 17f | 182 | 622 |
| Example 17g | 325 | 574 |
| Example 17h | 297 | 752 |
| Example 17i | 404 | 1050 |

### Testing Procedure 1:

The samples produced herein were processed into full coin cells for electrochemical performance testing using cyclic voltammetry. A slurry comprising the anode active materials, conductive additive and binder materials were cast onto a foil electrode to form an anode layer. A commercial separator and electrolyte were used as a standard, and a cathode was cast using a standard commercial NMC-811 powder. The testing was carried out at a controlled ambient temperature of 30° C. in Constant Current-Constant Voltage mode. A voltage window of 2.5-4.4V was used at a charge/discharge rate of 0.5C/1.0C after two formation cycles at 0.1C/0.1C. State of Health checks were carried out every 100 charge-discharge cycles at 0.33C/0.33C rates. Impedance spectroscopy (EIS) was also measured for each cell at 40% State of Charge every 100 cycles. The internal resistance was also recorded at 100% SOC for each charge-discharge cycle.

The discharge capacity for three cells was compared after 50 charge-discharge cycles. The three cells representing:
X=57 ppm Al on Graphite (85 wt %); Uncoated Si/G composite (15 wt %)=
⋄=57 ppm Al on Graphite (85 wt %); 73 ppm Al on Si/G composite (15 wt %)
▪=57 ppm Al on Graphite (85 wt %); 202 ppm Al on Si/G composite (15 wt %)

It has been discovered that the A1 ppm loading on the Si/G can be substantially higher than what becomes detrimental to cell capacity when applied to the Graphite particles themselves.

The discharge capacities for four cells using anode layer blends comprising 85% Al₂O₃-coated Graphite (57 ppm Al) and LiZrOx ALD-coated Si/G composite particles were compared after 50 charge-discharge cycles. The four cells representing:

| | | Zr |
|---|---|---|
| Example # | Li PPM | PPM |
| Example 17a | 160 | 498 |
| Example 17f | 182 | 622 |
| Example 17b | 280 | 825 |
| Example 17c | 305 | 1070 |

It has been discovered that though 300-500 ppm of Zr can enhance the performance of the Si/G composite particles when blended with an Al₂O₃-coated graphite powder, with increasing Zr loading and increasing Li loading, the performance slightly decreased until a threshold level of lithium and zirconium were present on the surfaces. The Li levels increased relatively linearly with Zr ppm levels. This is similar to what was observed for the Li[M]Ox coating when using graphite as the substrate and LiAlOx as the coating layer.

| | | Blend | [M]Ox ALD | [M], Li < 200 ppm | | [M], Li > 200 ppm |
|---|---|---|---|---|---|---|
| | Material | Ratio | Coating | Low [M] | High [M] | High |
| Anode Layer | Graphite | 10-85% | Al2O3 | 20 | 140 | 400 |
| Active | | | TiO2 | 20 | 140 | 560 |
| Materials | | | Li (from LiMOx) | 0 | <200 | >200 |
| | Si/G | 15-90% | Al2O3 | 200 | 500 | 1600 |
| | Composite | | TiO2 | 300 | 900 | 3600 |
| | | | ZrO2 | 300 | 900 | 3600 |
| | | | Li (from LiMOx) | 0 | <200 | >200 |

Table characterizing various levels observed from these materials and cells.

With 0-200 ppm Li in the coatings on graphite powders in a blended anode, ppm loadings of Al in Al₂O₃ and Ti in TiO₂ on graphite can range from 20-140 ppm. However, with >200 ppm Lithium added into the coating layers, Al and Ti ppm can range from 140-400 ppm.

With 0-200 ppm Li in the coatings on Si/G powders in a blended anode, ppm loadings of Al in Al₂O₃ can range from 200-400; Ti in TiO₂ and Zr in ZrO₂ can range from 300-900. However, with >200 ppm Lithium added into the coating layers, Al ppm can range from 500-1,600 ppm; Ti and Zr can range from 900-3,600 ppm.

Elemental mapping of Al₂O₃ coating on graphite particles by STEM/EDS showed preferential deposition of Al₂O₃ on edges and defect sites of graphite. Elemental mapping of Al₂O₃ coating on silicon-carbon particles by STEM/EDS showed no preferential deposition of Al₂O₃ on edges and defect sites.

The Table below details the slurry formulations for the electrodes. The slurry was mixed using a planetary mixer (Ross PDM-1/2) and coated onto either aluminum or copper foil (MTI Corporation) using a pilot-scale slot-die coater (Frontier Industrial Technology). The total mass loading of the cathode and anode was approximately 11.1 mg/cm² and 7.1 mg/cm², respectively, with a porosity of around 35%. Similar methodologies for slurry fabrication and coating procedures are described in our previous publications. The dimensions of the cathodes and anodes are 8.4 cm×5.6 cm and 8.6 cm×5.8 cm, respectively. The electrode balance (N/P ratio) of the single-layer pouch cells is maintained between 1.12 and 1.17. Celgard 2400 separators and the Gen 2 electrolyte (1.9 of volume factor) are used in the pouch cells.

TABLE
Electrode formulation

| Electrode | Cathode | Anode |
|---|---|---|
| Active material | 90 wt % coated or uncoated | 92 wt % coated or uncoated graphite |
| | NMC811 | |
| Conductive | 5 wt % carbon black (C65, Denka) | 2 wt % carbon black (C65, Denka) |
| agent | | |
| Binder | 5 wt % polyvinylidene difluoride | 6 wt % PVDF (KUREHA 9300), dissolved |
| | (PVDF, Solvay 5130), dissolved in | in NMP |
| | NMP | |

Abbreviations and corresponding formation conditions utilized in this study.

| Formation group | | Formation |
|---|---|---|
| abbreviation | Formation protocols | temperature |
| P1-30 | 4 cycles at C/5/-C/5 between 3.0 and 4.2 V | 30° C. |
| P2-30 | Charge at C/3 to 3.9 V, 4 shallow formation cycles | 30° C. |
| | at C/5 between 3.9 and 4.2 V, and then discharge at | |
| | C/3 to 3.0 V | |
| P1-45 | 4 cycles at C/5/-C/5 between 3.0 and 4.2 V | 45° C. |
| P2-45 | Charge at C/3 to 3.9 V, 4 shallow formation cycles | 45° C. |
| | at C/5 between 3.9 and 4.2 V, and then discharge at | |
| | C/3 to 3.0 V | |

Abbreviations and corresponding cell configurations

| Cell abbreviation | Cathode composition | Anode composition |
|---|---|---|
| UCUA | Uncoated NMC811 | Uncoated graphite |
| UCCA | Uncoated NMC811 | ALD coated graphite |
| CCUA | ALD coated NMC811 | Uncoated graphite |
| CCCA | ALD coated NMC811 | ALD coated graphite |

To assess the impact of baseline and fast formation protocols at different temperatures, we developed four formation protocols. Protocol P1 represents the baseline formation protocol, consisting of four full formation cycles between 3.0 V and 4.2 V. Protocol P2 represents the fast formation protocol, lasting approximately 14-16 hours. It consists of four shallow formation cycles between 3.9 V and 4.2 V at C/5, targeting the high state of charge (SOC) region where most SEI and CEI are formed. Moreover, during the first charge to 3.9 V and the final discharge from 3.9 V to 3.0 V, a C/3 rate is applied to further reduce the formation time. Both protocols were tested at two temperatures: 30° C. and 45° C. Additionally, we examined the effects of ALD coating on the anode or cathode on cell performance under different formation protocols. Four configurations of single-layer pouch cells were assembled and tested.

Generally, the formation cycles based on P1-30 and P1-45 took approximately 40 hours, while those based on P2-30 and P2-45 took around 14-16 hours. This indicates that the fast formation protocol (P2) leads to an around 60% reduction in formation time compared to P1. No significant differences in formation time for protocol P1 were observed between different cell configurations and temperatures. However, for protocol P2, slightly shorter formation times were observed in cathode-coated cells—CCUA and CCCA. This may be due to the insulating characteristics of the ALD Al₂O₃ layer coated on the cathode. The insulating Al₂O₃ layer deposited on the cathode increases interface resistance and leads to a higher potential on the cathode of CCUA, thereby resulting in shorter formation times for the full cell. Additionally, the higher potential on the cathode (CCUA) causes the average potential of the anode in CCUA to be higher than that in UCUA.

The total Coulombic Efficiency (CE) during the four formation procedures is compared across all cell configurations. Overall, P1-based protocols exhibit higher total CE compared to P2-based protocols, suggesting that more electrolyte decomposition occurs at high SOC (3.9V to 4.3V) compared to low SOC, resulting in more SEI and CEI formation. Comparing the CE between P1-30 and P1-45, lower CE is observed at the higher temperature of 45° C. for all cells (except for CCUA), likely due to increased electrolyte reduction/oxidation parasitic reactions at higher temperatures.

After the formation cycles, all cells were fully charged to 4.2 V at a C/5 cycling rate. The voltage of all cells was recorded over 24 hours. At a fully charged state, a slower voltage decrease during relaxation indicates a slower self-discharge, suggesting a more stable and passivating SEI formation. For all cell configurations, P1-30 exhibits the most stable voltage. Generally, the voltage drops faster for P2-30 compared to P1-30, except for the UCCA cell, which shows comparable voltage variation between P1-30 and P2-30. Comparing temperatures, all cell configurations formed at 45° C. show a more significant voltage drop, indicating a less stable SEI formation. Among different cell configurations, UCCA cells demonstrate the most stable voltage, while UCUA cells show the least stability.

Since the stability of the SEI/CEI significantly influences cell performance, we further investigated how different formation protocols influence the surface chemistry and SEI/CEI compositions. XPS analysis was conducted on the anodes and cathodes before formation, after P1-30, and after P2-30 formation protocols. The UCCA configuration was chosen due to its superior performance under the fast formation protocol P2-30. Only the low temperature P1-30 and P2-30 formation samples were analyzed, as high-temperature formations did not show promising performance in practice. For the anode, the SEI layers typically consist of an inner inorganic layer composed of Li₂CO₃, Li₂O, and an outer organic layer containing ROLi, ROCO₂ Li, etc. In the Cis spectra, the prominent C—C/C—H peak is observed at ˜284.5 eV. Peaks resulting from electrolyte decomposition include C—O (˜286.4 eV), C═O (˜288.2 eV), CO₃ (289.9 eV). Additionally, the CH₂—CF₂ peak at around 291.0 eV, originating from PVDF, is also present. Compared to the pristine anode, the anodes after formation show more C—O, C═O, and CO₃ peaks, and less CH₂—CF₂, indicating the formation of SEI. Compared to P2-30, slightly higher CO₃ and C—O peaks are observed on the P1-30 sample, indicating that the baseline formation protocol leads to a thicker SEI compared to the fast formation protocol. In the O₁ₛ spectra, a higher C═O (˜531.5 eV) signal observed on the anodes after formation compared to the pristine one also demonstrates SEI formation. In the F₁ₛ spectra, Li—F (˜684.7 eV) peaks appear on the anodes after formation but are absent in the pristine one. LiF is one of the main compounds of the SEI, resulting from the decomposition of LiPF₆. The higher Li—F observed on the P1-30 sample also indicates a thicker SEI formation. Moreover, Li—F is usually regarded as a beneficial SEI component due to its high mechanical strength and stable chemical properties, suggesting that a more stable SEI is formed after P1-30 compared to P2-30. The broad peaks in the Li₁ₛ spectra originate from Li₂O and Li₂CO₃. No Li₁ₛ profile is plotted as no Li single is found on the pristine anode. The formation of Li₂O and Li₂CO₃ on the anode surface is evident after formation. In general, on the anode of UCCA, a slightly thicker and more stable SEI is formed by P1-30 compared to P2-30. A similar analysis on the cathode, reveals more ROLi, Li₂O, Li₂CO₃, and lower amounts of LiF on the P1-30 cathode compared to P2-30.

In the UCCA cells, comparable R_{SEI} and R_{ct} values are seen for P1-30 and P2-30, demonstrating that fast formation with an ALD-coated anode performs as well as the long-duration formation. Additionally, the R_{SEI} for both P1-30 and P2-30 is much lower than for the high-temperature protocol, suggesting that thicker SEI/CEI layers are formed under high-temperature formation over time. Furthermore, R_{SEI} of UCCA is significantly lower than that of UCUA under both P1-30 and P2-30, indicating that the anode coating acts as a protective layer, leading to the formation of a thinner and more stable SEI, reducing Li loss due to electrolyte decomposition in the long run.

After 1000 aging cycles (except 500 cycles on CCUA_P1-30), all cell configurations were disassembled inside glove boxes and rinsed with DMC three times to remove electrolyte residue from the electrode surfaces.

In most cases, white residues indicative of lithium plating are observed on the anode surfaces. Among the UCUA anodes, the least amount of plating is evident in the P1-30 protocol. For UCCA, very little lithium plating is seen in both P1-30 and P2-30, while higher temperature formation protocols show increased white residues and some transparent deposits. In CCUA, some lithium plating is present in P1-30 after 500 cycles but is less severe compared to other conditions. In CCCA, P1-30 also exhibits the least plating, followed by P2-30, with more pronounced plating occurring in the higher temperature protocols.

In most cases, the baseline formation protocol P1-30 is more effective at preventing lithium deposition. Detailed micro-scale characterization by SEM on the anodes under P1-30 reveals clean graphite surfaces. Additionally, comparisons of anode surface chemical composition among all four formation protocols on the UCUA cell were conducted using XPS analysis. After 1000 cycles, the C1s spectra show little PVDF intensity across all cases, indicating the formation of thick SEI layers. The C₁ₛ and O₁ₛ spectra reveal more intense CO₃ signals in P1-45 and P2-45 compared to P1-30 and P2-30, suggesting that more Li₂CO₃ is deposited on the anodes after cycling under high-temperature formation. Comparing the F₁ₛ spectra, lower percentages of LiPF₆ and LiₓPO_{y}F_{z} and higher percentages of LiF are shown in UCCA, indicating a more stable SEI formed on the UCCA anode.

Among all cell configurations, UCCA exhibits the lowest lithium plating under all formation protocols, indicating that ALD coating on the anode provides better protection against lithium dendrite formation during long-term cycling. Particularly in the case of P2-30, UCCA significantly reduces lithium dendrite growth compared to other cell configurations. The SEM analysis of all anodes under P2-30 at two different magnifications, reveals very clear lithium dendrite structures on all other cell configurations except UCCA. Upon zooming in on areas without concentrated lithium plating, some impurities are observed on the graphite surface of CCUA and CCCA. As an example, the anode of CCCA_P2-30 was studied using EDX mapping to analyze the surface chemical compositions. Relatively high concentrations of O, P, and F are observed at the impurity locations, suggesting that these surface depositions (not dendritic structures) originate from electrolyte decomposition. In addition, XPS analysis under the P2-30 formation protocol also supports this statement. The C₁ₛ and O₁ₛ spectra reveal that the UCCA anode surface contains the least amount of Li₂CO₃. Furthermore, the F1 spectra indicate a lower percentage of LiPF₆ and LiₓPO_{y}F_{z}, alongside a higher percentage of LiF on the UCCA anode. These findings suggest that the SEI formed on the UCCA anode is more chemically and mechanically stable compared to other configurations. Similarly, by SEM, examining the UCCA anode surfaces under high temperature P1-45 and P2-45, reveals less lithium plating and impurities compared to other cell configurations.

Comparing the formation protocols at different temperatures, the optical images reveal that high-temperature protocols result in more impurities, including white dendrites and other deposits. Additionally, SEM characterizations of P1-45 and P2-45 further support this observation—more impurities (SEI-like) are shown compared to P1-30 and P2-30. When comparing all the anodes across different cell configurations from the optical images, CCUA appears to have the most impurities on the anode surface. This suggests that coating on the cathode may lead to faster degradation of the anode, particularly under inefficient formation conditions.

Concerning the cathodes, the optical images reveal no remarkable differences in appearance, except for some instances of electrode peeling observed during the disassembly process (especially for the cathodes under high-temperature formation protocols). Detailed morphological analysis was also conducted by SEM. Among all the cathodes under P1-30, no significant structural differences are observed. However, surface composition analyses by XPS reveal some differences—more LiF and Li₂CO₃ are present on the UCUA cathodes. This indicates that under P1-30, more CEI forms on UCUA, which could explain why UCUA shows slightly lower capacity retention after 1000 cycles compared to UCCA and CCCA. Similarly, comprehensive analysis of P2-30 cathodes was performed using SEM, XRD, and XPS techniques. SEM observations reveal some localized depositions—potentially electrolyte decomposition layers—on the CCCA cathodes, which are not observed on the other cathodes. The decomposition layer was investigated in detail using EDX mapping. Firstly, higher signals of C, P, and F are present in the deposition layer, likely related to decomposition products from the electrolyte. Secondly, a significant Mn intensity is observed in the deposition layer region, possibly originating from Mn dissolution during cycling and subsequent deposition on the cathode surface. XPS analysis of CCCA was conducted on areas without obvious decomposition layers. Among all cell configurations, more LiF and Li₂CO₃ are present on the CCUA cathode, suggesting thicker CEI formation. Combining SEM and XPS observations, it appears that more electrolyte decomposition occurs on the CCUA and CCCA cathode surfaces. To investigate the crystalline structure deformation of cycled cathodes compared to the pristine state, XRD patterns, particularly at the (108)/(110) and (113) peaks, were analyzed. When compared to the pristine NMC811, all cycled cathodes reveal a bigger splitting of the (108) and (110) peaks, accompanied by a shift of the (113) peak to higher degrees. These subtle yet telling observations point to lattice shrinkage along the a and b directions and an expansion along the c direction, indicating the loss of lithium in the cycled NMC materials. When comparing all the cycled cathodes, the trend in peak splitting and shift is observed as UCUA>UCCA>CCUA>CCCA. This indicates that UCUA cathodes experience the greatest lithium loss, reflecting the most severe structural degradation among the cathodes. Based on all characterizations of the P2-30 cathodes, we conclude that coating on cathodes leads to higher CEI formation while better preserving the cathode crystalline structures.

The surface morphology of cycled cathodes under high-temperature formation protocols was also characterized by SEM with images at two different magnifications for each condition. Overall, compared to the low-temperature formation, the cathode surfaces exhibit more electrolyte decomposition, transition metal deposition, and cathode pulverization. These observations demonstrate that high-temperature formation protocols lead to rapid degradation of cathode materials and accelerated electrolyte decomposition on the cathode surface.

Based on the analysis of the cathodes, we can draw the following conclusions: Generally, among all formation protocols, cathodes cycled under P1-30 exhibit the best structural retention. In contrast, high-temperature formation protocols lead to rapid cathode degradation. Among the cathodes cycled under P2-30, the UCCA cathode shows more proper CEI formation and better crystalline structure retention, showing that that ALD coating on the anode has a positive effect on the cathode CEI.

Our findings demonstrated that fast formation protocols significantly reduced formation time by approximately 60% compared to baseline protocols (from 40 down to 14-16 hours hours). However, XPS characterization revealed that P1-30 formed a slightly thinner and less stable SEI compared to P2-30. In consequence, fast formation (P2-30) leads to decreased long-term cell performance in UCUA, CCUA, and CCCA due to less stable SEI formation. Interestingly, P2-30 worked well on UCCA, resulting in comparable long-term cycling performance to P1-30. The artificial SEI on the anode (ALD coating) compensated for the less efficient SEI formation under fast formation, enhancing stability and reducing anode degradation during cycling. Under fast formation conditions, ALD coatings on cathodes provide benefits in terms of crystalline structure retention within the cathode powder during long-term cycling. However, this also results in thicker CEI formation and increased lithium plating and SEI formation on the anode side. This could be due to the insulating Al₂O₃ layer on the cathode introducing higher resistance, negatively influencing the formation potential on the anode surface. Regarding the formation temperature, higher formation temperatures (45° C.) results in increased parasitic reactions, higher electrolyte decomposition during formation, leading to overall poorer cell performance compared to formation at 30° C.

1. A battery, comprising:
an anode, a cathode, a separator separating the anode and cathode, and a Li electrolyte;
wherein the cathode comprises an active powder plus binder;
wherein the active powder does not have an ALD coating; and
wherein the anode comprises a coated graphite powder and a binder wherein the coated graphite powder comprises an ALD coating.

2. The battery of claim 1 wherein the anode has a surface comprising Li₂O and Li₂CO₃.

3. The battery of claim 1 wherein the ALD coating is applied by 2 to 10 cycles of exposure to trimethylaluminum and water.

4. The battery of claim 1 wherein the ALD coating comprises a Ti or Al oxide coating.

5. The battery of claim 1 wherein the active powder is uncoated.

6. The battery of claim 1 wherein the battery is treated by a plurality of shallow formation cycles at a voltage between 3.7 and 4.4 V and a temperature of 20 to 35° C. followed by a full discharge.

7. The battery of claim 1 wherein the graphite powder has a surface comprising at least 20 and at most 140 ppm of Al or at least 20 and at most 140 ppm of Ti.

8. The battery of claim 1 wherein the anode further comprises a silicon-carbon composite powder (particles comprising silicon and carbon within each particle) and comprising a coating of an aluminum oxide or a titanium oxide or a zirconium oxide disposed over the silicon-carbon particles.

9. The battery of claim 7 wherein the Ti or Al is present only in the coating.

10. The battery of claim 1 wherein the coated graphite powder comprises at most 5% by weight of one or more conductive additives and at most 5% by weight of one or more binder materials.

11. A method of forming a battery, comprising:
providing a battery comprising:
an anode, a cathode, a separator separating the anode and cathode, and a Li electrolyte;
wherein the cathode comprises an active powder plus binder; and
wherein the anode comprises a coated graphite powder and a binder wherein the coated graphite powder comprises an ALD coating;
and treating the battery with a plurality of shallow formation cycles at a voltage between 3.7 and 4.4 V and a temperature of 20 to 35° C. followed by a full discharge.

12. The method of claim 12 wherein the treatment comprises 3 to 5 shallow formation cycles at a rate of C/4 to C/6 at between 3.8 and 4.3 V and a temperature of 25 to 33° C. followed by a full discharge to 3 V.

13. The method of claim 12 wherein the treatment takes from 10 to 20 hours, or 13 to 17 hours.

14. The method of claim 11 wherein the battery is the battery of claim 1.

15. A composition, comprising: a mixture of a first powder and a second powder;
wherein the first powder comprises a graphite powder comprising a coating of an aluminum oxide or a boron oxide or a titanium oxide or a zirconium oxide;
wherein the second powder comprises a silicon-carbon composite powder (particles comprising silicon and carbon within each particle) and comprising a coating of an aluminum oxide or a titanium oxide or a zirconium oxide disposed over the silicon-carbon particles;
wherein the first powder surface comprises at least 20 and at most 140 ppm of Al or at least 20 and at most 140 ppm of B or at least 20 and at most 140 ppm of Ti or at least 20 and at most 140 ppm of Zr;
wherein the second powder surface comprises at least 200 ppm and at most 500 ppm of Al, or at least 300 ppm and at most 900 ppm of Ti, or at least 300 ppm and at most 1200 ppm of Zr.

16. The composition of claim 15 wherein the metal loading of the metal oxide disposed over the second powder is at least 50% greater than the metal loading of the metal oxide on the first powder; and in some preferred embodiments, at least 2× greater, in some embodiments in the range of at least 50% greater to 4× or less or 3× or less. “Metal loading of the metal oxide” refers to the ppm of the metal.

17. The composition of claim 15 wherein the first powder comprises a graphite powder comprising coating of an aluminum oxide; and wherein the first powder contains 20 to 140 ppm Al; preferably 70 to 100 ppm Al; wherein the second powder contains 340-430 ppm Al.

18. The composition of claim 15 wherein the non-silicon metals are present exclusively in the coatings.

19. The composition of claim 15 wherein (the metal loading of the metal oxide disposed over the second powder/surface area of the second powder) is at least 20% greater than (the metal loading of the metal oxide on the first powder/surface area of the first powder.

20. The composition of claim 15 further comprising at least 200 ppm Li in the first powder and the second powder.

21-25. (canceled)
